(19) United States
(12) Patent Application Publication
(10) Pub. No.: US 2026/0101775 A1
(43) Pub. Date: Apr. 9, 2026

(54) SEMICONDUCTOR PACKAGE AND MANUFACTURING METHOD THEREOF

(71) Applicant: Samsung Electronics Co., Ltd., Suwon-si (KR)

(72) Inventors: Jaejin LEE, Suwon-si (KR); Pilkyu KANG, Suwon-si (KR); Kunsang PARK, Suwon-si (KR); Sujin MOON, Suwon-si (KR); Jaewha PARK, Suwon-si (KR); Yubin SONG, Suwon-si (KR); Yunghee HAN, Suwon-si (KR)

(73) Assignee: Samsung Electronics Co., Ltd., Suwon-si (KR)

(21) Appl. No.: 19/174,395

(22) Filed: Apr. 9, 2025

(30) Foreign Application Priority Data
Oct. 8, 2024 (KR) 10-2024-0136820

(51) Int. Cl. H01L 23/00; H01L 23/538; H01L 25/00; H01L 25/16

(52) U.S. Cl. CPC H10W 70/611; H10W 70/635; H10W 90/00; H10W 72/952; H10W 90/792; H10W 90/794

(57) ABSTRACT

Provided are a semiconductor package having a structure capable of improving thermal characteristics and enhancing interconnect density, and a manufacturing method thereof. The semiconductor package includes a first semiconductor chip having a first upper surface which is an active surface and a first lower surface opposite to the first upper surface, and having a through-electrode arranged in the first semiconductor chip, a second semiconductor chip stacked on the first semiconductor chip, the second semiconductor chip having a second lower surface which is an active surface and a second upper surface opposite to the second lower surface and having a size larger than the first semiconductor chip in a horizontal direction, and an external through-electrode placed below the second semiconductor chip and adjacent to the first semiconductor chip, wherein the second semiconductor chip is stacked on the first semiconductor chip through hybrid copper bonding (HCB).

### CROSS-REFERENCE TO RELATED APPLICATION

This application is based on and claims priority under 35 USC § 119 to Korean Patent Application No. 10-2024-0136820, filed on Oct. 8, 2024, in the Korean Intellectual Property Office, the disclosure of which is incorporated by reference herein in its entirety.

### BACKGROUND

The inventive concept relates to a semiconductor package, and more particularly, to a semiconductor package having a structure in which a large-sized semiconductor chip and a small-sized semiconductor chip are stacked, and a manufacturing method thereof.

With the rapid development of the electronics industry and demand of users, electronic devices have become smaller and lighter. As electronic devices have become smaller and lighter, semiconductor packages used in electronic devices have also become smaller and lighter, and semiconductor packages have also been required to have high reliability along with high performance and high capacity. In order to achieve miniaturization, light weight, high performance, high capacity, and high reliability, research and development have continuously been conducted on semiconductor chips including through-silicon via (TSV) structures and semiconductor packages in which such semiconductor chips are stacked.

### SUMMARY

The inventive concept provides a semiconductor package having a structure capable of improving thermal characteristics and enhancing interconnect density, and a manufacturing method thereof.

In addition, the problems to be solved by the technical idea of the inventive concept are not limited to the problems mentioned above, and other problems may be clearly understood by those skilled in the art from the description below.

According to an aspect of the inventive concept, there is provided a semiconductor package including a first semiconductor chip having a first upper surface which is an active surface and a first lower surface opposite to the first upper surface, and having a through-electrode arranged in the first semiconductor chip, a second semiconductor chip stacked on the first semiconductor chip, the second semiconductor chip having a second lower surface which is an active surface and a second upper surface opposite to the second lower surface and having a size larger than the first semiconductor chip in a horizontal direction, and an external through-electrode placed below the second semiconductor chip and adjacent to the first semiconductor chip, wherein the second semiconductor chip is stacked on the first semiconductor chip through hybrid copper bonding (HCB).

According to another aspect of the inventive concept, there is provided a semiconductor package including a first semiconductor chip having a first upper surface which is an active surface and a first lower surface opposite to the first upper surface and having a through-electrode arranged in the first semiconductor chip, a second semiconductor chip stacked on the first semiconductor chip, the second semiconductor chip having a second lower surface which is an active surface and a second upper surface opposite to the second lower surface and having a larger size than the first semiconductor chip in a horizontal direction, a sealant sealing the first semiconductor chip on a lower surface of the second semiconductor chip, an external through-electrode placed below the second semiconductor chip and adjacent to the first semiconductor chip, the external through-electrode penetrating the sealant, and external connection terminals respectively arranged on a lower surface of the external through-electrode and a lower surface of a first lower pad disposed on the first lower surface of the first semiconductor chip, wherein the second semiconductor chip is stacked on the first semiconductor chip through hybrid copper bonding (HCB), and the lower surface of the external through-electrode is substantially coplanar with the lower surface of the first lower pad.

According to another aspect of the inventive concept, there is provided a semiconductor package including a package substrate, a first semiconductor device on the package substrate, and at least one second semiconductor device placed on the package substrate and adjacent to the first semiconductor device, wherein the first semiconductor device has a package structure including a first semiconductor chip having a first upper surface as an active surface and a first lower surface opposite to the first upper surface and having a through-electrode arranged in the first semiconductor chip, a second semiconductor chip stacked on the first semiconductor chip, having a second lower surface as an active surface and a second upper surface opposite to the second lower surface, and having a larger size than the first semiconductor chip in a horizontal direction, and an external through-electrode placed below the second semiconductor chip and adjacent to the first semiconductor chip, and the second semiconductor chip is stacked on the first semiconductor chip through hybrid copper bonding (HCB).

### BRIEF DESCRIPTION OF THE DRAWINGS

Embodiments will be more clearly understood from the following detailed description taken in conjunction with the accompanying drawings in which:

FIGS. 1A and 1B are a cross-sectional view and an enlarged view of a semiconductor package according to an embodiment, respectively;

FIGS. 2A to 2C are cross-sectional views of semiconductor packages according to embodiments;

FIGS. 3A and 3B are a perspective view and a cross-sectional view of a system package according to an embodiment, respectively;

FIGS. 4A to 4D are cross-sectional views of system packages according to embodiments;

FIGS. 5A to 5G are cross-sectional views briefly illustrating a method of manufacturing a semiconductor package, according to an embodiment;

FIGS. 6A to 6H are cross-sectional views illustrating the process of operation 5a in more detail;

FIGS. 7A and 7B are cross-sectional views illustrating the process from operation of FIG. 5A to operation of FIG. 5B in detail; and

FIGS. 8A to 8I are cross-sectional views illustrating the process from operation of FIG. 5C to the operation of FIG. 5D in detail.

### DETAILED DESCRIPTION OF THE EMBODIMENTS

Hereinafter, embodiments are described in detail with reference to the accompanying drawings. Like reference numerals are used for the same components in the drawings, and redundant descriptions thereof are omitted.

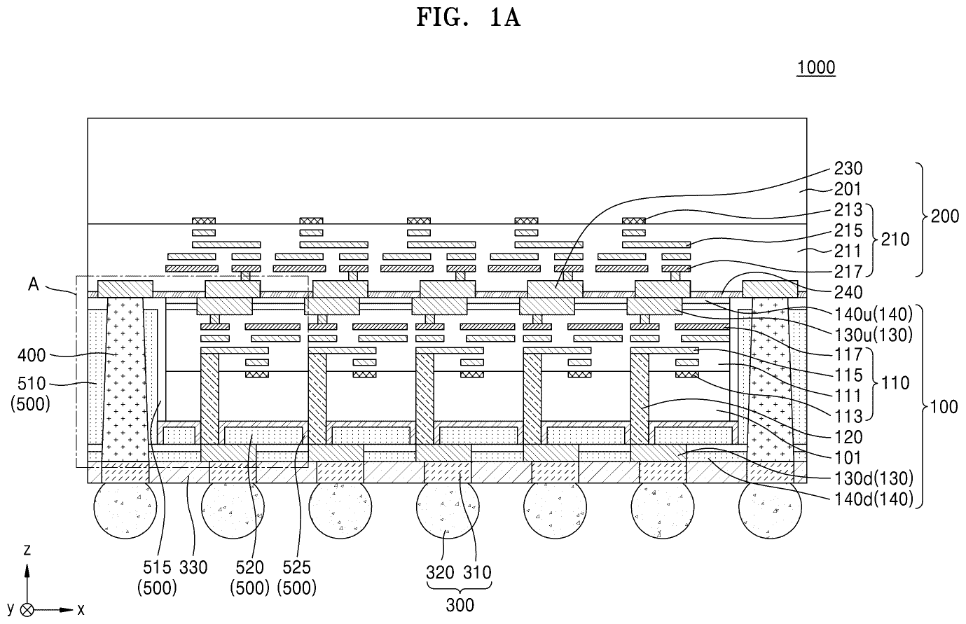

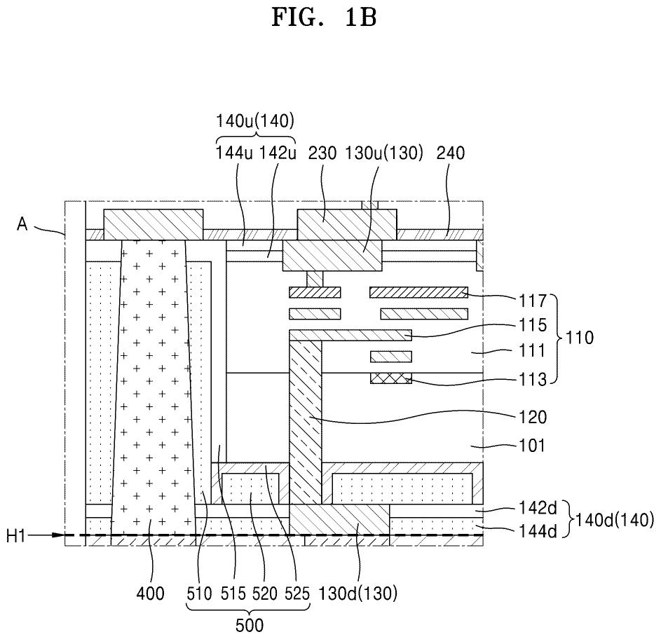

FIG. 1A is a cross-sectional view of a semiconductor package 1000 according to an embodiment, and FIG. 1B is an enlarged cross-sectional view of portion A of FIG. 1A.

Referring to FIGS. 1A and 1B, the semiconductor package 1000 of the present embodiment may include a first semiconductor chip 100, a second semiconductor chip 200, an external connection terminal 300, an external through-electrode 400, and a sealant 500.

The first semiconductor chip 100 is placed below the second semiconductor chip 200 and may have a smaller size than that of the second semiconductor chip 200. For example, in a horizontal direction, i.e., in each of an x-direction and a y-direction, the width of the first semiconductor chip 100 may be less than the width of the second semiconductor chip 200.

The first semiconductor chip 100 may include, for example, a logic chip. For example, the first semiconductor chip 100 may be a modem chip that supports communication of the second semiconductor chip 200. However, the type of the first semiconductor chip 100 is not limited to the modem chip. For example, the first semiconductor chip 100 may support the operation of the second semiconductor chip 200 or may include various types of logic chips for various signal processing together with the second semiconductor chip 200. The logic chip is described in detail in the description of the second semiconductor chip 200.

In some embodiments, the first semiconductor chip 100 may include a memory chip. Accordingly, the first semiconductor chip 100 may include a number of memory devices therein. The memory devices may include, for example, dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM) devices. In the semiconductor package 1000 of the present embodiment, when the first semiconductor chip 100 includes a memory chip, the first semiconductor chip 100 may include, for example, an SRAM chip.

The first semiconductor chip 100 may include a first semiconductor substrate 101, a first active layer 110, a through-electrode 120, a first chip pad 130, and a first protective layer 140. The first semiconductor substrate 101 may constitute a body of the first semiconductor chip 100 and may include silicon (Si). However, the material of the first semiconductor substrate 101 is not limited to Si. For example, the first semiconductor substrate 101 may include other semiconductor materials, such as germanium (Ge), Si—Ge, or a group III-V compound, such as GaP, GaAs, GaSb, etc. In addition, in some embodiments, the first semiconductor substrate 101 may include a silicon-on-insulator (SOI) substrate or a germanium-on-insulator (GOI) substrate.

The first active layer 110 may include a first integrated circuit layer and a first interconnection layer. The first integrated circuit layer may include a plurality of integrated devices 113. The integrated device 113 may include, for example, a transistor. However, the integrated device 113 is not limited to the transistor. The first interconnection layer may be disposed on the first integrated circuit layer. The first interconnection layer may include an interlayer insulating layer 111, interconnections 115, and an internal pad 117. The interconnections 115 are arranged in two or more layers, and the interconnections 115 of different layers may be connected to each other through vertical vias. The internal pad 117 is positioned above the first interconnection layer and may include aluminum (Al). However, the material of the internal pad 117 is not limited to Al.

The through-electrode 120 may extend through the first semiconductor substrate 101 in a vertical direction, i.e., a z direction. Because the first semiconductor substrate 101 includes Si, the through-electrode 120 may correspond to a through silicon via (TSV). For reference, the through-electrode 120 may be classified into a via-first structure formed before the formation of the integrated circuit layer, a via-middle structure formed after the formation of the integrated circuit layer but before the formation of the interconnection layer, and a via-last structure formed after the formation of the interconnection layer. In FIG. 1A, the through-electrode 120 may correspond to the via-middle structure. However, the inventive concept is not limited thereto, and in the semiconductor package 1000 of the present embodiment, the through-electrode 120 may be formed in the via-first or via-last structure.

The first chip pad 130 may include a lower pad 130d and an upper pad 130u. The lower pad 130d may be placed on a lower surface of the first semiconductor chip 100. As shown in FIG. 1A, the lower pad 130d may be directly connected to the through-electrode 120. The upper pad 130u may be placed on an upper surface of the first semiconductor chip 100. The upper pad 130u may be connected to the through-electrode 120 through the first interconnection layer. The first chip pad 130 may include, for example, at least one of aluminum (Al), copper (Cu), nickel (Ni), tungsten (W), platinum (Pt), and gold (Au). In the semiconductor package 1000 of the present embodiment, the first chip pad 130 may include Cu. However, the material of the first chip pad 130 is not limited to Cu.

The first protective layer 140 may be placed on the lower surface and upper surface of the first semiconductor chip 100. The first protective layer 140 may include a lower protective layer 140d on the lower surface of the first semiconductor chip 100 and an upper protective layer 140u on the upper surface of the first semiconductor chip 100. In the semiconductor package 1000 of the present embodiment, each of the lower protective layer 140d and the upper protective layer 140u may have a multilayer structure. For example, as illustrated in FIG. 1B, the lower protective layer 140d may include a first lower insulating layer 142d and a second lower insulating layer 144d, and the upper protective layer 140u may include a first upper insulating layer 142u and a second upper insulating layer 144u. However, the number of layers of each of the lower protective layer 140d and the upper protective layer 140u is not limited to two layers. The first protective layer 140 may include, for example, an oxide film, a nitride film, a carbon film, a polymer, or combinations thereof.

In the first semiconductor chip 100, the upper surface may be an active surface (front side: FS), and the lower surface may be an inactive surface (back side: BS). In other words, an upper surface of the first interconnection layer may correspond to the front side (FS) of the first semiconductor chip 100, and the lower surface of the first semiconductor substrate 101 may correspond to the back side (BS) of the first semiconductor chip 100. Accordingly, the lower protective layer 140d and the lower pad 130d may be placed on the lower surface which is the inactive surface of the first semiconductor chip 100, and the upper protective layer 140u and the upper pad 130u may be placed on the upper surface which is the active surface of the first semiconductor chip 100.

In addition, the lower pad 130d is located as a structure that penetrates the lower protective layer 140d, and the lower pad 130d may be exposed from the lower surface of the lower protective layer 140d. The lower pad 130d may be directly connected to the lower surface of the through-electrode 120, as described above. The upper pad 130u may be located as a structure that penetrates the upper protective layer 140u, and the upper pad 130u may be exposed from the upper surface of the upper protective layer 140u. The upper pad 130u may be connected to the internal pad 117 of the first interconnection layer and may be connected to the upper surface of the through-electrode 120 through the interconnections 115.

The second semiconductor chip 200 may be stacked on the first semiconductor chip 100. The second semiconductor chip 200 may include, for example, a logic chip. Accordingly, the second semiconductor chip 200 may include a number of logic devices therein. Logic devices may include, for example, an AND, a NAND, an OR, a NOR, an exclusive OR (XOR), an exclusive NOR (XNOR), an inverter (INV), an adder (ADD), a delay (DLY), a filter (FIL), and multiplexers (MXT/MXIT), an OR/AND/INVERTER (OAI), an AND/OR (AO), an AND/OR/INVERTER (AOI), a D flip-flop, a reset flip-flop, a master-slave flip-flop, a latch, a counter, or buffer devices. Logic devices may perform a variety of signal processing, including analog signal processing, analog-to-digital (A/D) conversion, and control. The second semiconductor chip 200 may be referred to as a central processing unit (CPU) chip, a micro-processor unit (MPU) chip, a graphics processing unit (GPU) chip, a neural processing unit (NPU) chip, an application processor (AP) chip, or a control chip, depending on functions thereof.

The second semiconductor chip 200 may include a second semiconductor substrate 201, a second active layer 210, a second chip pad 230, and a second protective layer 240. The second semiconductor substrate 201 may be based on a semiconductor substrate. Descriptions of the second semiconductor substrate 201 are the same as those given above for the first semiconductor substrate 101 of the first semiconductor chip 100.

The second active layer 210 may be placed below the second semiconductor substrate 201. The second active layer 210 may include a second integrated circuit layer and a second interconnection layer. The second integrated circuit layer may include a plurality of integrated devices 213. The second interconnection layer may include an interlayer insulating layer 211, interconnections 215, and an internal pad 217. Descriptions of the second active layer 210 are the same as those given above for the first active layer 110 of the first semiconductor chip 100.

However, the integrated devices 113 included in the first integrated circuit layer may be different from the integrated devices 213 included in the second integrated circuit layer. For example, when the first semiconductor chip 100 is a memory chip and the second semiconductor chip 200 is a logic chip, the integrated device 113 of the first integrated circuit layer may include a memory device and the integrated device 213 of the second integrated circuit layer may include a logic device. When the first semiconductor chip 100 is a logic chip, the integrated device 113 of the first integrated circuit layer may also include a logic device.

The second chip pad 230 may be placed on a lower surface of the second semiconductor chip 200. In detail, the second chip pad 230 may be placed on a lower surface of the second active layer 210 and may be connected to the internal pad 217 of the second interconnection layer. The material of the second chip pad 230 is the same as the material of the first chip pad 130 of the first semiconductor chip 100.

The second protective layer 240 may be placed on a lower surface of the second semiconductor chip 200. In FIG. 1A, the second protective layer 240 is illustrated as a single-layer structure but is not limited thereto, and the second protective layer 240 may include a multilayer structure. The material of the second protective layer 240 is the same as the material of the first protective layer 140 of the first semiconductor chip 100.

In the second semiconductor chip 200, the lower surface may be a front side (FS) which is an active surface, and the upper surface may be a back side (BS) which is an inactive surface. In other words, a lower surface of the second interconnection layer may correspond to the front side (FS) of the second semiconductor chip 200, and an upper surface of the second semiconductor substrate 201 may correspond to the back side (BS) of the second semiconductor chip 200. Accordingly, the second protective layer 240 and the second chip pad 230 may be placed on the lower surface which is the active surface of the second semiconductor chip 200. The second chip pad 230 may be located as a structure that penetrates the second protective layer 240, and the second chip pad 230 may be exposed from the lower surface of the second protective layer 240. The second chip pad 230 may be connected to the internal pad 217 of the second interconnection layer.

The first semiconductor chip 100 may be directly bonded to the second semiconductor chip 200 through hybrid copper bonding (HCB). Here, HCB may refer to a combined bonding of a pad-to-pad bonding in which pads of the first semiconductor chip 100 are bonded to pads of the second semiconductor chip 200 and insulator-to-insulator bonding in which insulating layers of the first semiconductor chip 100 are bonded to insulating layers of the second semiconductor chip 200. Because the pads usually include copper (Cu), pad-to-pad bonding is also referred to as copper-to-copper (Cu-to-Cu) bonding. In addition, in insulator-to-insulator bonding, the insulator may include, for example, a nitride film, such as SiNx, or an oxide film, such as SiO₂. However, the material of the insulating layer is not limited to nitride or oxide films.

In the semiconductor package 1000 of the present embodiment, the bonding of the first semiconductor chip 100 and the second semiconductor chip 200 is not limited to HCB. For example, in some embodiments, the first semiconductor chip 100 may be bonded to the second semiconductor chip 200 through connection terminals, such as bumps. In addition, the first semiconductor chip 100 may be bonded to the second semiconductor chip 200 through an anisotropic conductive film (ACF). Here, ACF refers to an ACF that is formed by mixing fine conductive particles with an adhesive resin to form a film and making the film conductive in only one direction.

The external connection terminal 300 may be placed on the lower surface of the first semiconductor chip 100 and the lower surface of the external through-electrode 400. On the lower surface of the first semiconductor chip 100, the external connection terminal 300 may be placed on the lower pad 130d of the first semiconductor chip 100. The external connection terminal 300 may include a pillar 310 and a bump 320. The pillar 310 may have a cylindrical shape and may include, for example, nickel (Ni), copper (Cu), palladium (Pd), platinum (Pt), gold (Au), or combinations thereof. In the semiconductor package 1000 of the present embodiment, the pillar 310 may include Cu. In some embodiments, the pillar 310 may serve as a chip pad, and a chip pad, i.e., a lower pad, may not be formed on the lower surface of the first semiconductor chip 100. A package protective layer 330 may be formed on the lower surfaces of the first semiconductor chip 100 and the external through-electrode 400, and the pillar 310 may be located as a structure that penetrates the package protective layer 330. The package protective layer 330 may include, for example, solder resist (SR). However, the material of the package protective layer 330 is not limited to SR.

The bump 320 may be placed on the pillar 310. The bump 320 may include, for example, solder. Solder may include tin (Sn), indium (In), bismuth (Bi), antimony (Sb), copper (Cu), silver (Ag), zinc (Zn), and/or alloys thereof. For example, solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and the like. In some embodiments, the bump 320 may be referred to as a solder, a solder bump, or the like. Meanwhile, an intermediate layer may be formed on a contact interface between the pillar 310 and the bump 320. The intermediate layer may include an intermetallic compound (IMC) formed by a reaction between metal materials included in the pillar 310 and the bump 320 at a relatively high temperature.

The external through-electrode 400 may be placed horizontally adjacent to the first semiconductor chip 100 and at the bottom of the second semiconductor chip 200. The external through-electrode 400 may have a structure extending in the vertical direction, i.e., the z direction, by penetrating the sealant 500. The external through-electrode 400 may connect the second chip pad 230 to the external connection terminal 300. For example, power/ground may be provided to the second semiconductor chip 200 through the external through-electrode 400.

The external through-electrode 400 may be formed by forming a through-hole in the sealant 500 and filling the through-hole with a metal material. The external through-electrode 400 may include, for example, Cu, and may be formed together with the lower pad 130d through plating. Accordingly, as indicated by the dashed line in FIG. 1B, the lower surface of the external through-electrode 400 and the lower surface of the lower pad 130d may each have a first height H1 and form substantially the same plane. That is, the lower surface of the external through-electrode 400 may be substantially coplanar with the lower surface of the lower pad 130d. Here, being substantially coplanar may include not only being completely coplanar but also being approximately coplanar within a tolerance caused by, for example, a process error or a measurement error recognizable by one of ordinary skill in the art. Furthermore, being substantially coplanar may include not only a case in which elements are completely on the same plane, but also a case in which the elements are approximately on the same plane within a tolerance caused by, for example, a process error or a measurement error recognizable by one of ordinary skill in the art.

In the semiconductor package 1000 of the present embodiment, a plurality of external through-electrodes 400 may be arranged in one row in the y direction, adjacent to opposite sides of the first semiconductor chip 100 in the x direction. In addition, in other embodiments, the external through-electrodes 400 may be arranged in two or more rows in the y direction. Meanwhile, the external through-electrode 400 may penetrate the sealant 500, which is a dielectric layer, and thus may correspond to a through-dielectric via (TDV).

The sealant 500 may be placed on the lower surface of the second semiconductor chip 200 and may cover portions of the side surface and lower surface of the first semiconductor chip 100. In addition, the sealant 500 may cover the side of the external through-electrode 400. Furthermore, the sealant 500 may cover a portion of the lower surface of the second semiconductor chip 200. In detail, the sealant 500 may include a side sealant 510 and a lower sealant 520. The side sealant 510 may cover a side surface of the first semiconductor chip 100, and the lower sealant 520 may cover the lower surface of the first semiconductor chip 100. As can be seen from FIG. 1A, the side sealant 510 may be placed on a first gapfill liner 515, and the lower sealant 520 may be placed on a second gapfill liner 525.

The sealant 500 may include an organic-inorganic composite material. For example, the sealant 500 may include a resin containing silica filler. Here, the resin may correspond to an organic material, and the silica filler may correspond to an inorganic material. Meanwhile, the sealant 500 may include a material having a low dielectric constant. For example, the sealant 500 may include a material having permittivity of 3.8 or less. In some embodiments, the sealant 500 may include a polymer, such as polyimide (PI), polybenzoxazole (PBO), polyhydroxystyrene (PHS), epoxy, benzocyclobutene (BCB) series, etc.

Meanwhile, the sealant 500 may be formed through a process of filling the gap between the first semiconductor chips 100 when manufacturing the semiconductor package 1000. Accordingly, the sealant 500 may be referred to as a gapfill layer. In addition, in the semiconductor package 1000 of the present embodiment, the sealant 500 may include an organic-inorganic composite material with a high filling ratio, thereby effectively filling the gap.

In the semiconductor package 1000 of the present embodiment, the first semiconductor chip 100 having a small size may be placed at the bottom and the second semiconductor chip 200 having a large size is placed at the top, and the first semiconductor chip 100 may be combined with the second semiconductor chip 200 in a front-to-front (F2F) manner so that the thermal characteristics of the second semiconductor chip 200, which is a logic chip, may be significantly improved. In addition, there is no need to place separate dummy chips. Furthermore, the number of bonding pads may be increased regardless of the through-electrode 120 of the first semiconductor chip 100. That is, the number of bonding pads may be increased by shrinking the pitch of the upper pad 130u of the first semiconductor chip 100 and the second chip pad 230 of the second semiconductor chip 200. In this manner, by reducing the pitch and increasing the number of bonding pads, the interconnect density may be increased even in the same product, thereby improving the speed of the device and being effectively utilized for next generation chip scaling.

In addition, the semiconductor package 1000 of the present embodiment may improve power transmission characteristics through the external through-electrode 400. In addition, the semiconductor package 1000 of the present embodiment may configure a GPU/CPU/SoC chip, etc., depending on the type of the second semiconductor chip 200. Furthermore, the semiconductor package 1000 of the present embodiment may be utilized in a server-oriented semiconductor device or a mobile-oriented semiconductor device, depending on the type of logic devices included in the second semiconductor chip 200.

For reference, in the case of a package structure in which a large logic chip is placed at the bottom and a small SRAM chip is placed at the top, the logic chip may be combined with the SRAM chip in a front-to-back (F2B) structure, and dummy chips may be placed on top of the logic chip to dissipate heat from the logic chip. In addition, the presence of dummy chips may increase the size of the logic chip. Meanwhile, because the placement area of the through-electrode is restricted by the keep out zone (KOZ) of the logic chip, there is a limit to the increase in the number of bonding pads, and therefore, there is a limit to the improvement in interconnect density. Here, the KOZ refers to an area around the transistor in which patterning cannot be performed, and a through-electrode cannot be placed in the KOZ.

Recently, the power consumption of logic chips in high performance computing (HPC)/server-oriented products has continuously increased and the die size has been increased to implement high-performance logic functions, so 3D integrated circuit (IC) or logic chiplet technology has emerged. Here, 3D IC may refer to that a memory chip and a logic chip are combined together and utilized as a single integrated chip, like the structure of the semiconductor package 1000 of the present embodiment. In addition, logic chiplets refer to semiconductor chips manufactured to be discriminated according to the size and function of the devices and may be used with substantially the same meaning as 3D IC. In addition, the need for 3D packages in which logic chips and memory chips are stacked in 3D to implement high performance of the system has increased. Performance factors to consider in 3D packages include power delivery, thermal characteristics, and cost, and in particular, improvement of thermal characteristics has become more important due to the high power consumption of logic chips. In order to secure the power transmission characteristics of a large logic chip, the logic chip may be generally placed at the bottom and a small memory chip may be stacked at the top. However, in this structure, because the logic chip is placed at the bottom, the thermal characteristics may not be good, and accordingly, a dummy chip may be required.

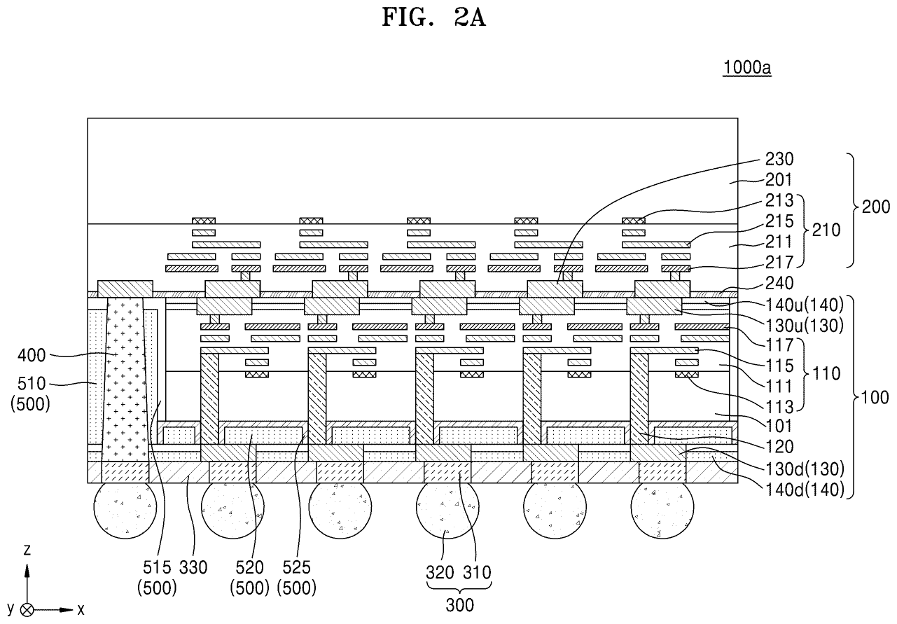

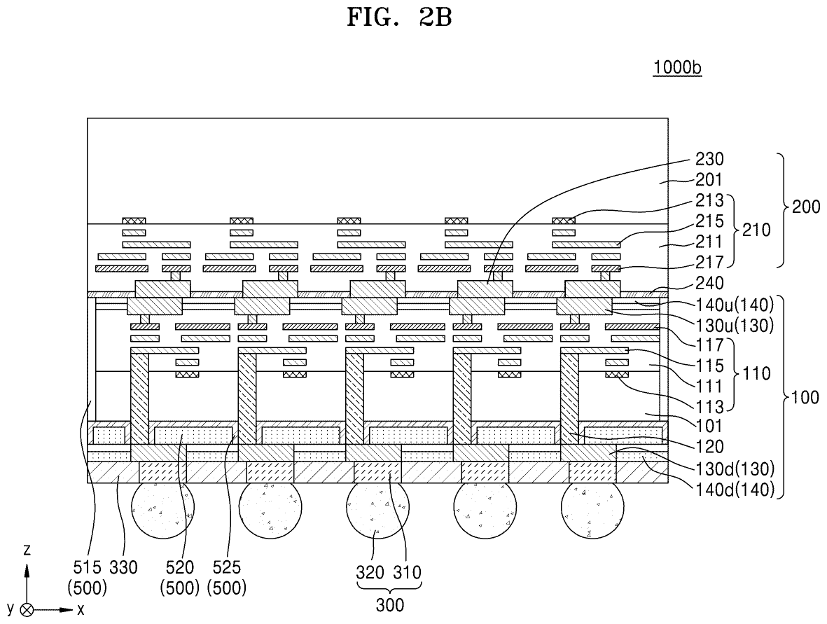

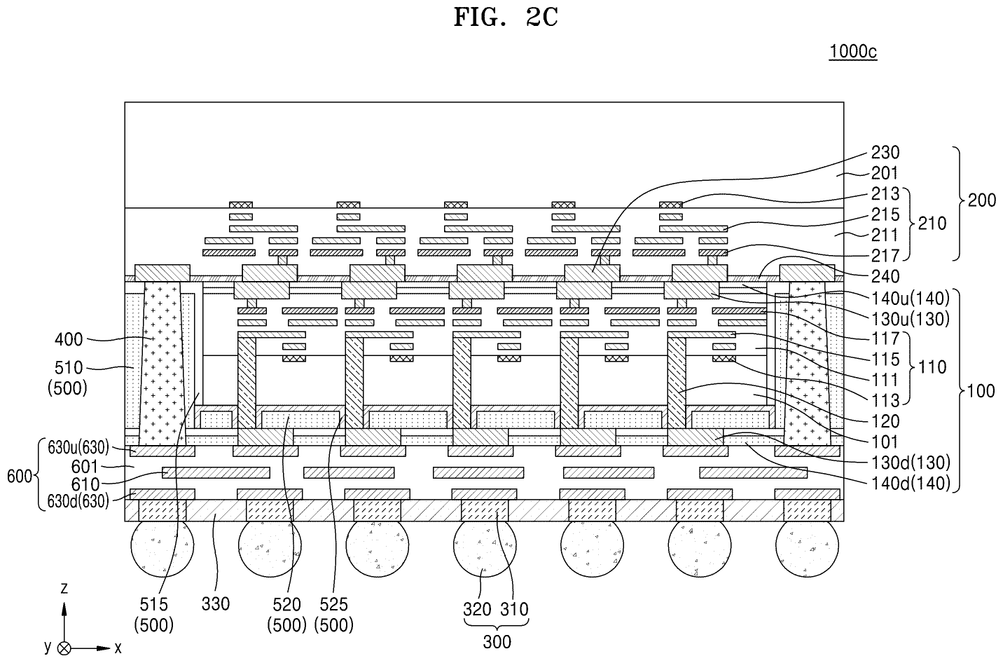

FIGS. 2A to 2C are cross-sectional views of semiconductor packages 1000a, 1000b, and 1000c according to embodiments. The descriptions already given above with reference to FIGS. 1A and 1B are briefly given or omitted.

Referring to FIG. 2A, the semiconductor package 1000a of the present embodiment may differ from the semiconductor package 1000 of FIG. 1A in the arrangement structure of the external through-electrode 400. In detail, the semiconductor package 1000a of the present embodiment may include the first semiconductor chip 100, the second semiconductor chip 200, the external connection terminal 300, the external through-electrode 400, and the sealant 500. The first semiconductor chip 100, the second semiconductor chip 200, the external connection terminal 300, and the sealant 500 are the same as those of the semiconductor package 1000 described above with reference to FIG. 1A.

In the semiconductor package 1000a of the present embodiment, the external through-electrode 400 may be arranged adjacent to only one side of the first semiconductor chip 100 in the x direction, for example, only the left side. Accordingly, the first semiconductor chip 100 may be coupled to the second semiconductor chip 200 while being shifted to the right in the x direction. A plurality of external through-electrodes 400 may be arranged in one row in the y direction adjacent to the left side of the first semiconductor chip 100 in the x direction. In addition, in other embodiments, the external through-electrodes 400 may be arranged in two or more rows in the y direction adjacent to the left side of the first semiconductor chip 100 in the x direction.

Referring to FIG. 2B, the semiconductor package 1000b of the present embodiment may differ from the semiconductor package 1000 of FIG. 1A in that an external through-electrode is not arranged. In detail, the semiconductor package 1000b of the present embodiment may include the first semiconductor chip 100, the second semiconductor chip 200, the external connection terminal 300, and the sealant 500. The first semiconductor chip 100, the second semiconductor chip 200, the external connection terminal 300, and the sealant 500 are the same as those of the semiconductor package 1000 described above with reference to FIG. 1A.

In the semiconductor package 1000b of the present embodiment, because an external through-electrode is not arranged, power/ground to the second semiconductor chip 200 may be provided through the through-electrode 120 of the first semiconductor chip 100. When the through-electrode 120 of the first semiconductor chip 100 is sufficient, the size of the second semiconductor chip 200 may be reduced by not arranging a separate external through-electrode, and accordingly, the total size of the semiconductor package 1000b may be reduced.

Referring to FIG. 2C, the semiconductor package 1000c of the present embodiment may differ from the semiconductor package 1000 of FIG. 1A in that the semiconductor package 1000c further includes a redistribution layer 600. In detail, the semiconductor package 1000c of the present embodiment may include a first semiconductor chip 100, a second semiconductor chip 200, an external connection terminal 300, an external through-electrode 400, a sealant 500, and a redistribution layer 600. The first semiconductor chip 100, the second semiconductor chip 200, the external connection terminal 300, the external through-electrode 400, and the sealant 500 are the same as those of the semiconductor package 1000 described above with reference to FIG. 1A.

In the semiconductor package 1000c of the present embodiment, the redistribution layer 600 may be placed below the first semiconductor chip 100 and the external through-electrode 400. The redistribution layer 600 may include a redistribution insulating layer 601, redistribution lines 610, and redistribution pads 630. The redistribution insulating layer 601 may include, for example, a photo imageable dielectric (PID) resin and may further include an inorganic filler. However, the material of the redistribution insulating layer 601 is not limited to the PID resin. When the redistribution lines 610 are arranged in two or more layers, the redistribution lines 610 in different layers may be connected to each other through vertical vias.

The redistribution pad 630 may be placed on a lower surface and upper surface of the redistribution layer 600. The redistribution pad 630 may include a lower redistribution pad 630d positioned on the lower surface of the redistribution layer 600 and an upper redistribution pad 630u positioned on the upper surface of the redistribution layer 600. The external connection terminal 300 may be placed on the lower redistribution pad 630d. The upper redistribution pad 630u may be connected to the through-electrode 120 and the external through-electrode 400.

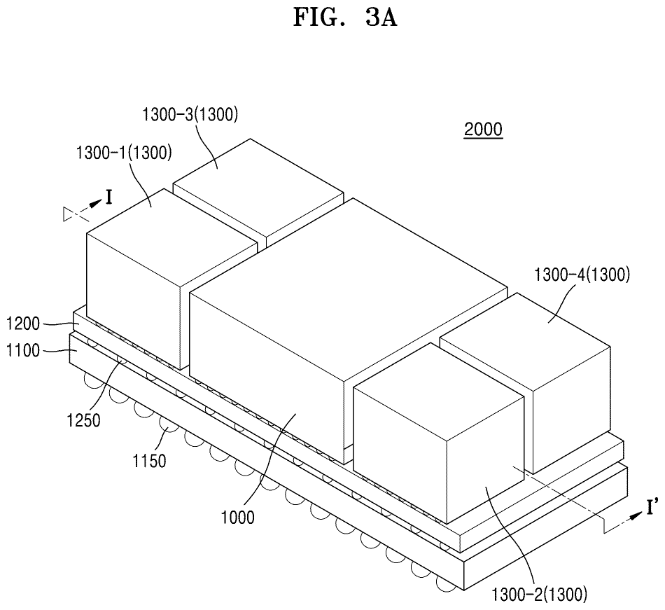

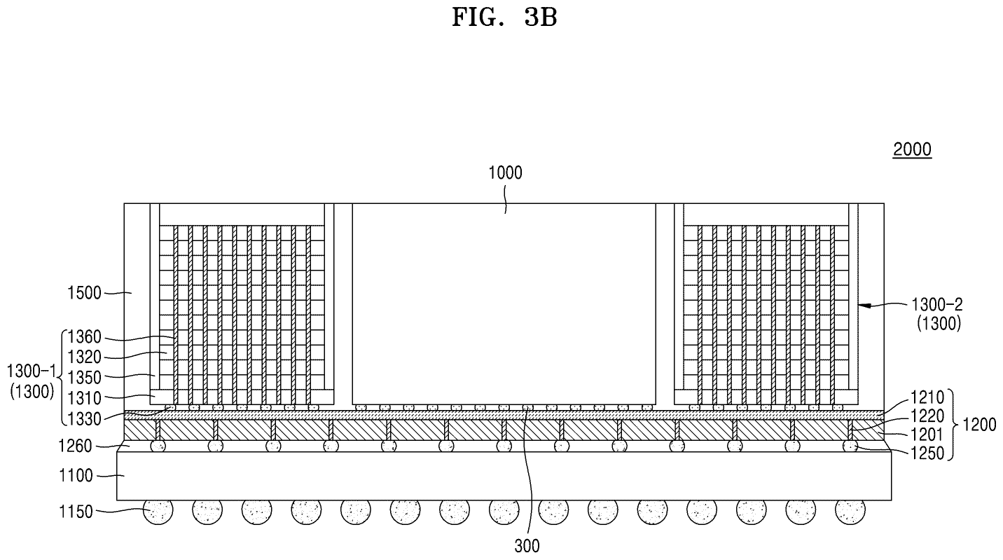

FIG. 3A is a perspective view of a system package 2000 according to an embodiment, and FIG. 3B corresponds to a cross-sectional view taken along line I-I′ of FIG. 3A. Descriptions are given with reference to FIGS. 1A and 1B together, and the descriptions already given above with reference to FIGS. 1A to 2C are briefly given or omitted.

Referring to FIGS. 3A and 3B, the system package 2000 of the present embodiment may include the semiconductor package 1000, a package substrate 1100, an interposer 1200, a semiconductor device 1300, and an external sealant 1500.

The semiconductor package 1000 may be, for example, the semiconductor package 1000 of FIG. 1A. Accordingly, the semiconductor package 1000 may include the first semiconductor chip 100, the second semiconductor chip 200, the external connection terminal 300, the external through-electrode 400, and the sealant 500. The second semiconductor chip 200 may be larger than the first semiconductor chip 100, and the first semiconductor chip 100 may be combined with the second semiconductor chip 200 through HCB. Meanwhile, in FIGS. 3A and 3B, the semiconductor package 1000 shows only the external connection terminal 300 and the remaining portions are simply illustrated in a block form.

The package substrate 1100 may be a support substrate, and the interposer 1200, the semiconductor package 1000, and the semiconductor device 1300 may be stacked on the package substrate 1100. The package substrate 1100 may include at least one layer of interconnection lines therein. When the interconnection lines are formed in multiple layers, the interconnection lines of other layers may be connected to each other through vertical vias. The package substrate 1100 may be formed based on, for example, a ceramic substrate, a printed circuit board (PCB), an organic substrate, an interposer substrate, etc. A first connection terminal 1150 may be placed on a lower surface of the package substrate 1100. The system package 2000 may be stacked on an external system substrate or main board through the first connection terminal 1150.

The interposer 1200 may include an interposer substrate 1201, an interconnection layer 1210, a through-electrode 1220, and a second connection terminal 1250. The semiconductor package 1000 and the semiconductor device 1300 may be mounted on the package substrate 1100 via the interposer 1200. The interposer 1200 may connect the semiconductor package 1000 to the semiconductor device 1300. In addition, the interposer 1200 may connect the semiconductor package 1000 and the semiconductor device 1300 to the package substrate 1100.

The interposer substrate 1201 may include, for example, Si. Accordingly, the interposer 1200 may be a Si interposer. The through-electrode 1220 may extend through the interposer substrate 1201. Because the interposer substrate 1201 includes Si, the through-electrode 1220 may correspond to a TSV. The through-electrode 1220 may extend to the interconnection layer 1210 and be connected to interconnections of the interconnection layer 1210. According to an embodiment, the interposer 1200 may include only an interconnection layer therein and may not include a through-electrode. The interconnection layer 1210 may be placed on an upper or lower surface of the interposer substrate 1201. For example, the positional relationship between the interconnection layer 1210 and the through-electrode 1220 may be relative. A pad on an upper surface of the interposer 1200 may be connected to the through-electrode 1220 through the interconnection layer 1210.

The second connection terminal 1250 may be placed on the lower surface of the interposer 1200 and connected to the through-electrode 1220. The interposer 1200 may be stacked on the package substrate 1100 via the second connection terminal 1250. The second connection terminal 1250 may be connected to the pad on the upper surface of the interposer 1200 through the through-electrode 1220 and the interconnection lines of the interconnection layer 1210.

In the system package 2000 of the present embodiment, the interposer 1200 may be used for the purpose of converting an electrical signal or transmitting an electrical signal between the semiconductor package 1000 and the semiconductor device 1300. Accordingly, the interposer 1200 may not include devices, such as active devices or passive devices. However, in some embodiments, the interposer 1200 may include devices for controlling signal transmission. Meanwhile, an underfill 1260 may be filled between the interposer 1200 and the package substrate 1100 and between the second connection terminals 1250. In other embodiments, the underfill 1260 may be replaced with an adhesive layer or adhesive film.

As illustrated in FIG. 3A, the semiconductor device 1300 may include first to fourth semiconductor devices 1300-1 to 1300-4. For example, two semiconductor devices 1300 may be placed on opposite sides of the semiconductor package 1000 on the interposer 1200. However, in the system package 2000 of the present embodiment, the number of semiconductor devices 1300 is not limited to four. For example, one to three, or five or more semiconductor devices 1300 may be placed on the interposer 1200.

The semiconductor device 1300 may include, for example, a high bandwidth memory (HBM) package. However, the semiconductor device 1300 is not limited to the HBM package. For example, the semiconductor device 1300 may have a single chip structure or a general package structure other than the HBM package.

In more detail, when the semiconductor device 1300 is an HBM package, the semiconductor device 1300 may include a base chip 1310 and a plurality of memory chips 1320 on the base chip 1310, and the base chip 1310 and the memory chips 1320 may include a through-electrode 1360 therein. Meanwhile, the uppermost memory chip among the memory chips 1320 may not include the through-electrode 1360.

The base chip 1310 may include a logic chip. Accordingly, the base chip 1310 may include logic devices therein. The base chip 1310 is placed below the memory chips 1320 to integrate signals from the memory chips 1320 and transmit the integrated signal externally and may also transmit a signal and power from the outside to the memory chips 1320. Accordingly, the base chip 1310 may be referred to as a buffer chip or a control chip.

The memory chips 1320 may be stacked on the base chip 1310. In the semiconductor device 1300 of the system package 2000 of the present embodiment, twelve memory chips 1320 may be stacked on the base chip 1310. However, the number of memory chips 1320 stacked on the base chip 1310 is not limited to twelve. For example, two to eleven or thirteen or more memory chips 1320 may be stacked on the base chip 1310.

Each of the memory chips 1320 may include, for example, a DRAM chip. The memory chips 1320 may be referred to as core chips. Meanwhile, the memory chip 1320 may be stacked on the base chip 1310 or the lower memory chip 1320 through the aforementioned HCB, bonding using a connection terminal, or bonding using ACF.

A third connection terminal 1330 may be placed on the lower surface of the base chip 1310. The third connecting terminal 1330 may be connected to the through-electrode 1360. The semiconductor device 1300 may be mounted on the interposer 1200 via the third connection terminal 1330. The memory chips 1320 on the base chip 1310 may be sealed by an internal sealant 1350.

An external sealant 1500 may cover and seal the semiconductor package 1000 and the semiconductor devices 1300 on the interposer 1200. As illustrated in FIG. 3B, the external sealant 1500 may not cover the upper surfaces of the semiconductor package 1000 and the semiconductor devices 1300. However, in some embodiments, the external sealant 1500 may cover the upper surface of at least one of the semiconductor package 1000 and the semiconductor devices 1300.

For reference, the structure of the system package 2000 as in the present embodiment is called a 2.5D package structure, which may be a relative concept for a 3D package structure in which all semiconductor chips are stacked together and there is no interposer. Both a 2.5D package structure and a 3D package structure may be included in a system-in-package (SIP) structure. In addition, the system package 2000 of the present embodiment is also a semiconductor package but is named as a system package in order to distinguish the system package 2000 from the semiconductor package 1000 which is a component.

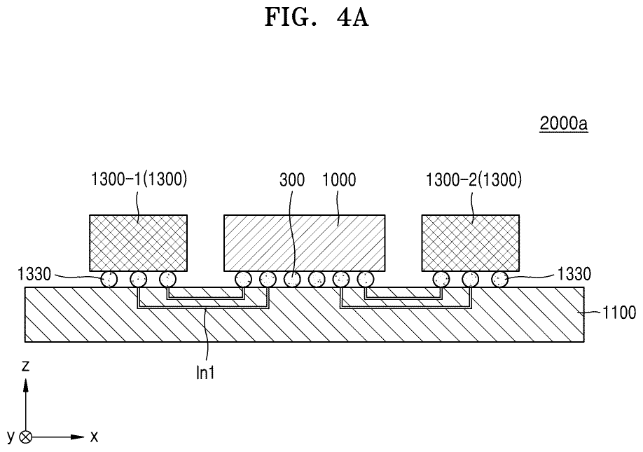

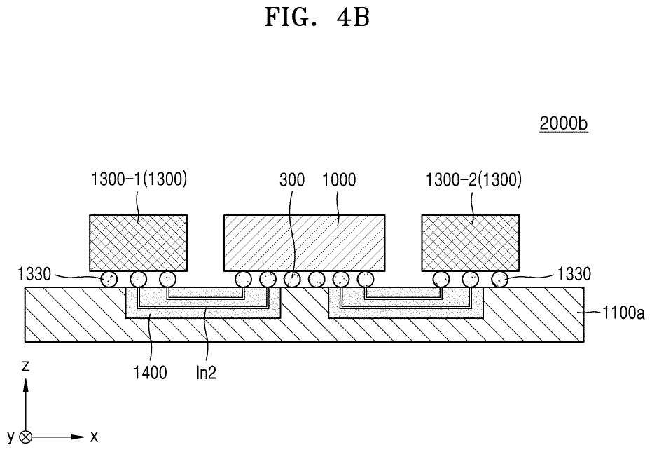

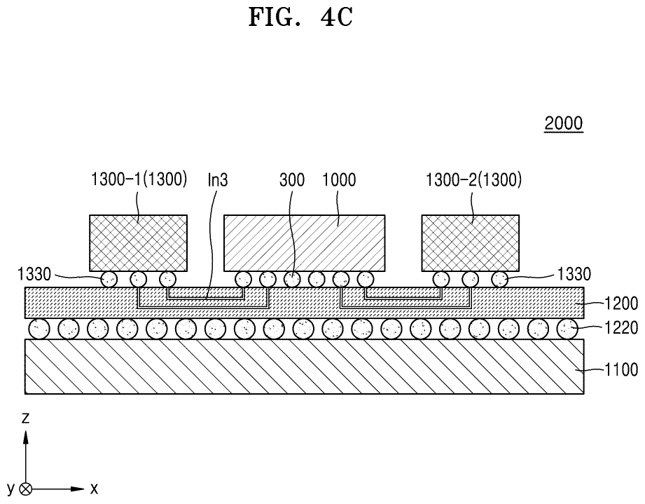

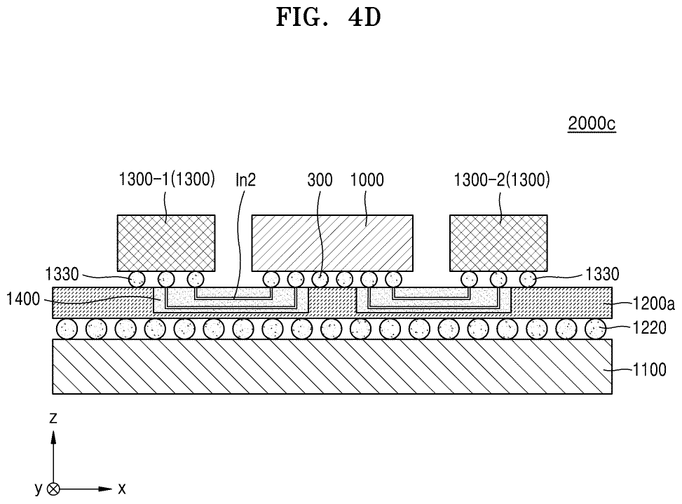

FIGS. 4A to 4D are cross-sectional views of system packages according to embodiments. The descriptions already given above with reference to FIGS. 1A to 3B are briefly given or omitted. For reference, FIGS. 4A to 4D are cross-sectional views corresponding to FIG. 3B, and from the perspective of the connection structure between the semiconductor package 1000 and the semiconductor device 1300, only the semiconductor package 1000, the mounting substrate 1100 or 1200, and the semiconductor device 1300 are schematically illustrated, and the first connection terminal and the external sealant, etc. are not illustrated.

Referring to FIG. 4A, a system package 2000a of the present embodiment may include a semiconductor package 1000, a package substrate 1100, and a semiconductor device 1300. The system package 2000a of the present embodiment may not include an interposer compared to the system package 2000 of FIG. 3B. Accordingly, the semiconductor package 1000 may be mounted directly on the package substrate 1100 via the external connection terminal 300. In addition, the semiconductor device 1300 may be mounted directly on the package substrate 1100 via the third connection terminal 1330. A detailed structure and function of the package substrate 1100, the semiconductor package 1000, and the semiconductor device 1300 are the same as those of the system package 2000 described above with reference to FIG. 3B. As illustrated in FIG. 4A, in the system package 2000a of the present embodiment, the semiconductor package 1000 and the semiconductor device 1300 may be connected through a first interconnect In1 of the package substrate 1100. The first interconnect In1 may be a portion of the interconnection lines of the package substrate 1100.

Referring to FIG. 4B, a system package 2000b of the present embodiment may include a semiconductor package 1000, a package substrate 1100a, a semiconductor device 1300, and a Si bridge 1400. The system package 2000b of the present embodiment may further include an Si bridge 1400 compared to the system package 2000a of FIG. 4A.

The Si bridge 1400 may be placed within the package substrate 1100a, as shown in FIG. 4B. The Si bridge 1400 may be placed inside the package substrate 1100a at a corresponding position between the semiconductor package 1000 and the semiconductor device 1300. In addition, the Si bridge 1400 may overlap a portion of the semiconductor package 1000 and a portion of the semiconductor device 1300. In the system package 2000b of the present embodiment, the semiconductor device 1300 may be placed on opposite sides of the semiconductor package 1000 in the x direction. Therefore, the Si bridge 1400 may be placed on opposite sides of the semiconductor package 1000 in the x direction.

The Si-bridge 1400 may include a second interconnect In2 therein. The Si bridge 1400 may connect the semiconductor package 1000 to the semiconductor device 1300 through the second interconnect In2. As a result, in the system package 2000b of the present embodiment, the semiconductor package 1000 may be connected to the semiconductor device 1300 using the Si bridge 1400 separately placed within the package substrate 1100a.

Referring to FIG. 4C, the system package 2000 of the present embodiment may be substantially identical to the system package 2000 of FIG. 3B. Accordingly, the system package 2000 of the present embodiment may include the semiconductor package 1000, the package substrate 1100, the interposer 1200, and the semiconductor device 1300. The semiconductor package 1000 may be mounted on the interposer 1200 via the external connection terminal 300, and the semiconductor device 1300 may be mounted on the interposer 1200 via the third connection terminal 1330. As illustrated in FIG. 4C, in the system package 2000 of the present embodiment, the semiconductor package 1000 may be connected to the semiconductor device 1300 through a third interconnect In3 of the interposer 1200. The third interconnect In3 may include an interconnection line of the interconnection layer 1210 and the through-electrode 1220 or may include only an interconnection line of the interconnection layer 1210.

Referring to FIG. 4D, a system package 2000c of the present embodiment may include the semiconductor package 1000, the package substrate 1100, an interposer 1200a, the semiconductor device 1300, and the Si bridge 1400. The system package 2000c of the present embodiment may further include the Si-bridge 1400 compared to the system package 2000 of FIG. 4C.

The Si bridge 1400 may be placed within the interposer 1200a, as illustrated in FIG. 4D. The Si bridge 1400 may be placed inside the interposer 1200a at a corresponding position between the semiconductor package 1000 and the semiconductor device 1300. In addition, the Si bridge 1400 may overlap a portion of the semiconductor package 1000 and a portion of the semiconductor device 1300. In the system package 2000c of the present embodiment, the semiconductor device 1300 may be placed on opposite sides of the semiconductor package 1000 in the x direction. Therefore, the Si bridge 1400 may be placed on opposite sides of the semiconductor package 1000 in the x direction.

The Si-bridge 1400 may include the second interconnect In2 therein. The Si bridge 1400 may connect the semiconductor package 1000 to the semiconductor device 1300 through the second interconnect In2. As a result, in the system package 2000c of the present embodiment, the semiconductor package 1000 may be connected to the semiconductor device 1300 using the Si bridge 1400 separately placed within the interposer 1200a.

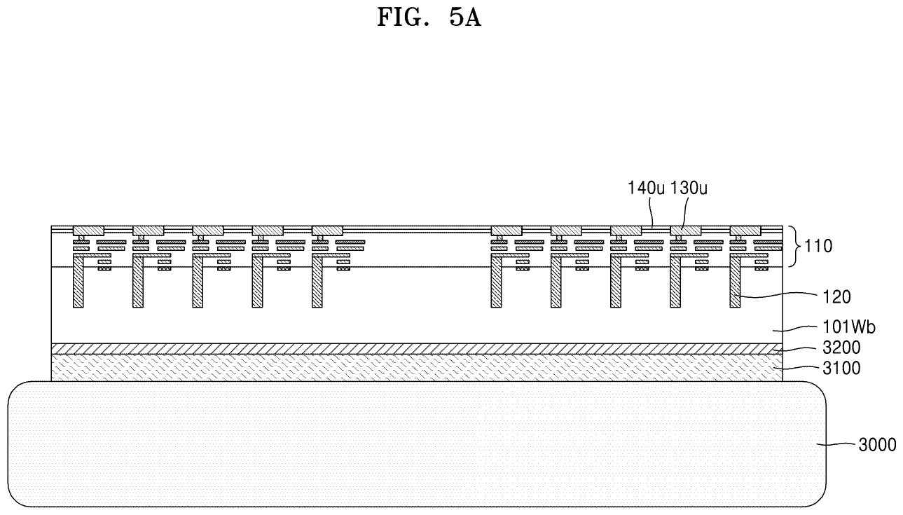

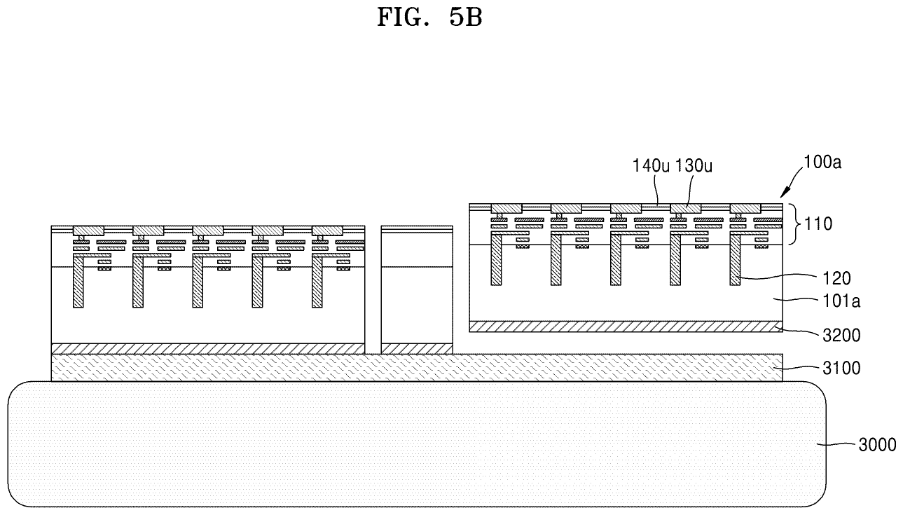

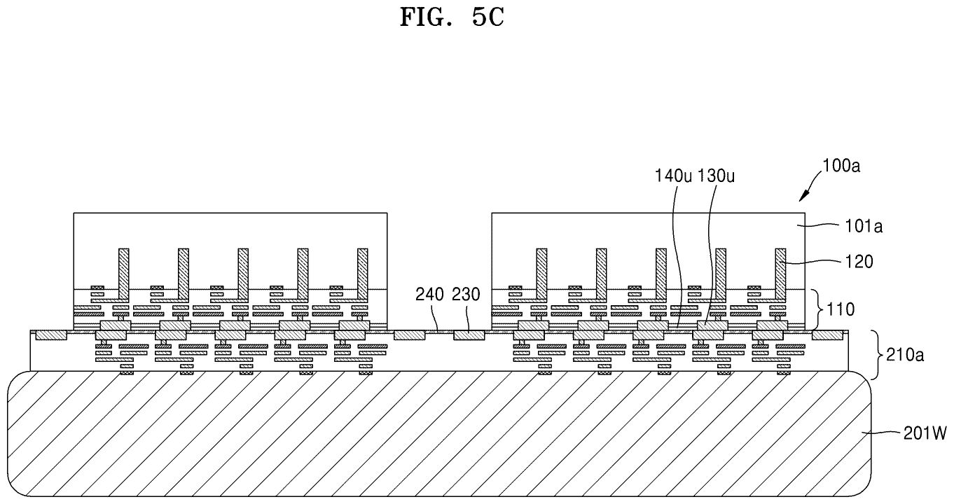

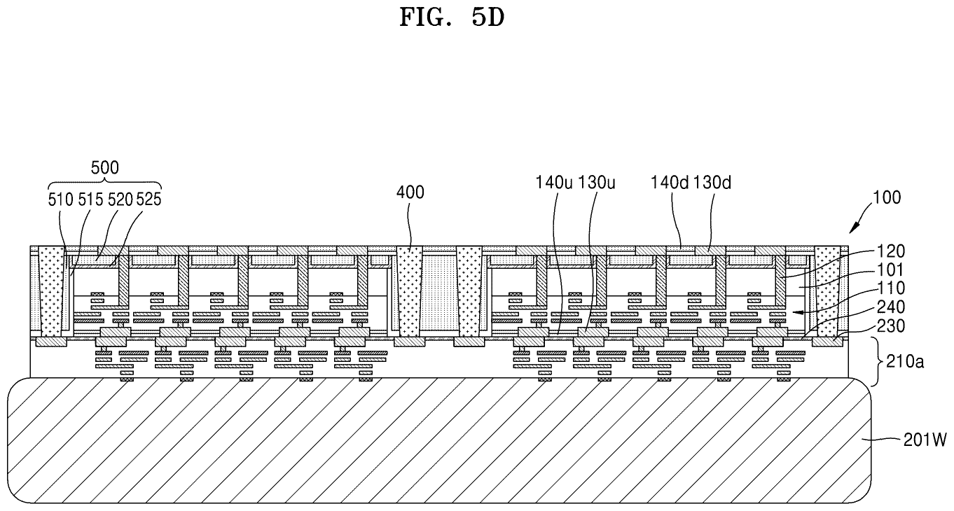

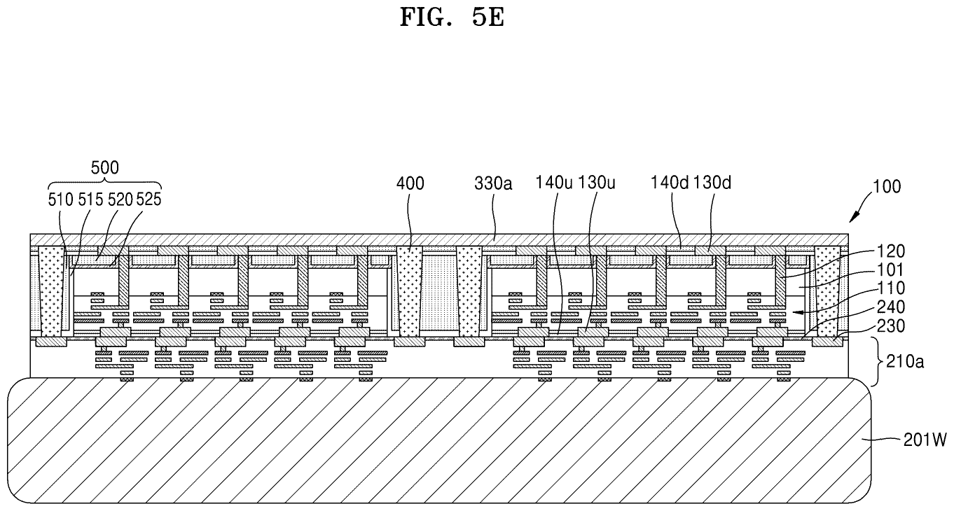

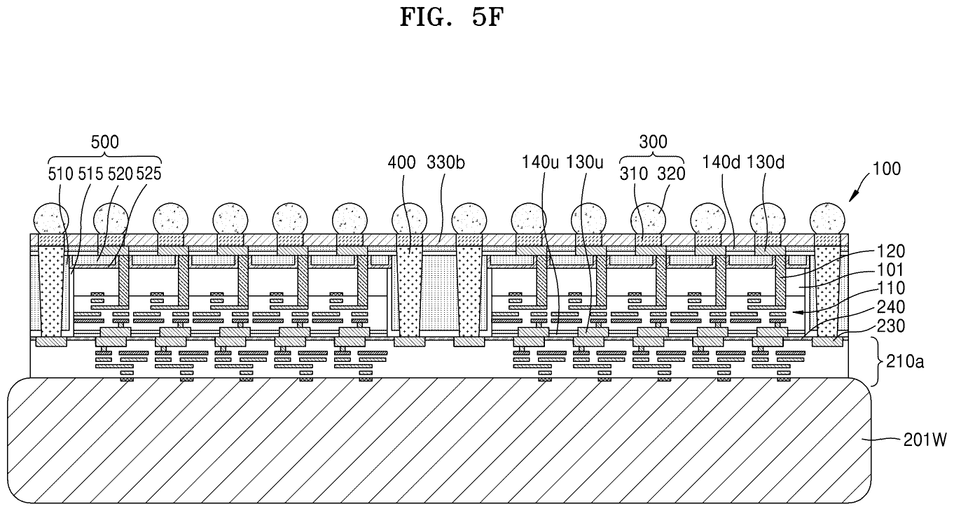

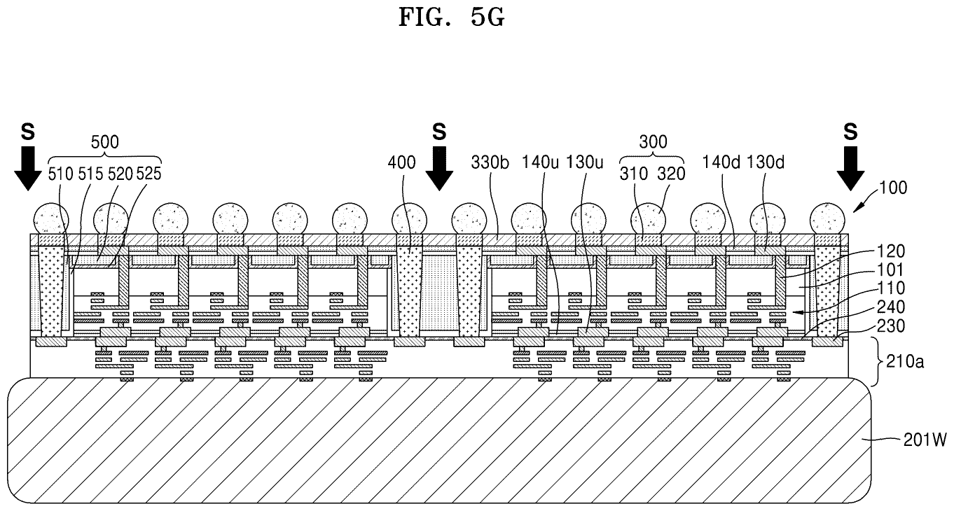

FIGS. 5A to 5G are cross-sectional views briefly illustrating a method of manufacturing a semiconductor package, according to an embodiment. Descriptions are given with reference to FIGS. 1A and 1B together, and descriptions already given above in the description of FIGS. 1A to 4D are briefly given or omitted.

Referring to FIG. 5A, in the method of manufacturing a semiconductor package of the present embodiment, a plurality of initial first semiconductor chips are formed on a first semiconductor substrate 101Wb. The first semiconductor substrate 101Wb may be in a wafer state and may be bonded and fixed to a first carrier substrate 3000 through an adhesive layer. The adhesive layer may include, for example, a temporary bonding material (TBM) layer 3100 and a release layer 3200.

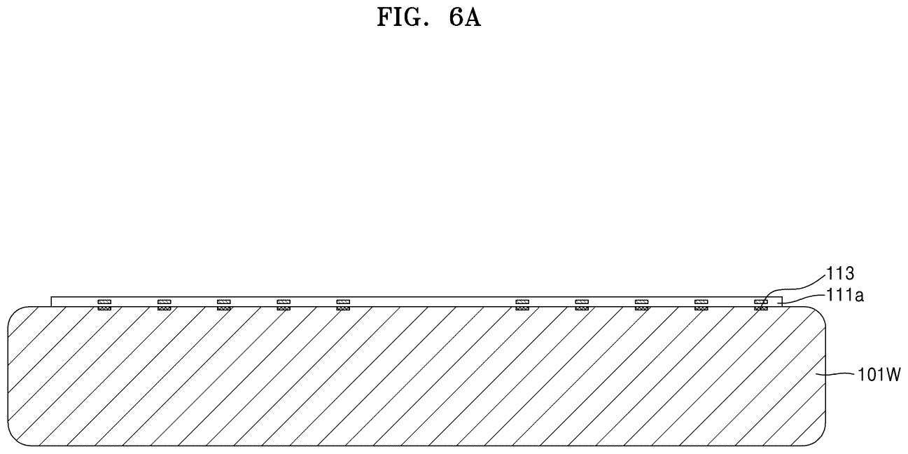

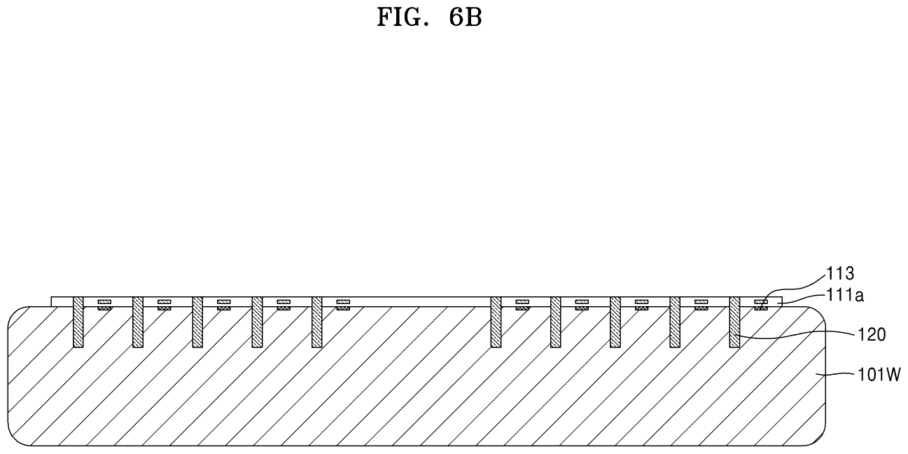

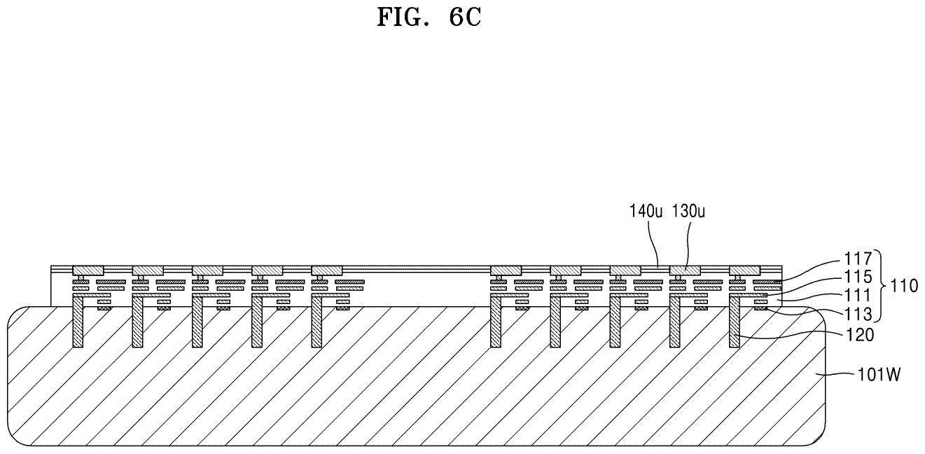

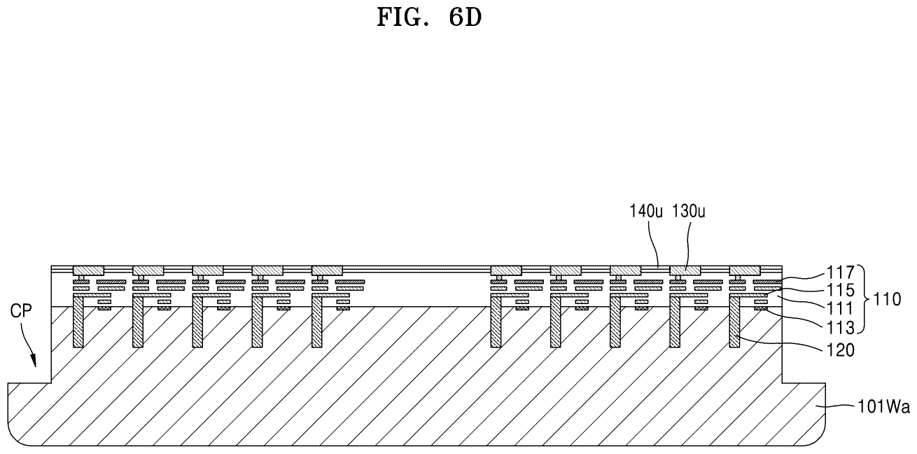

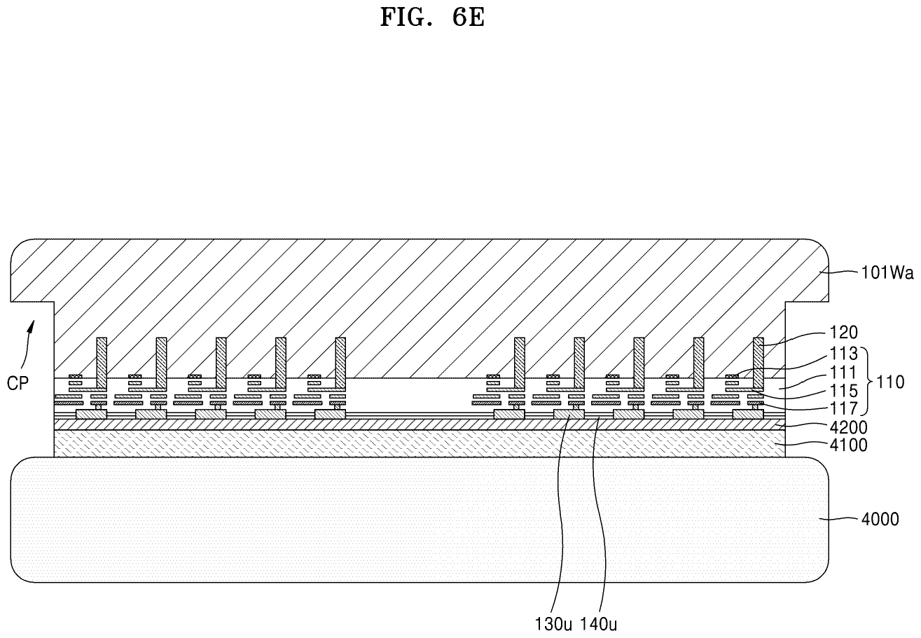

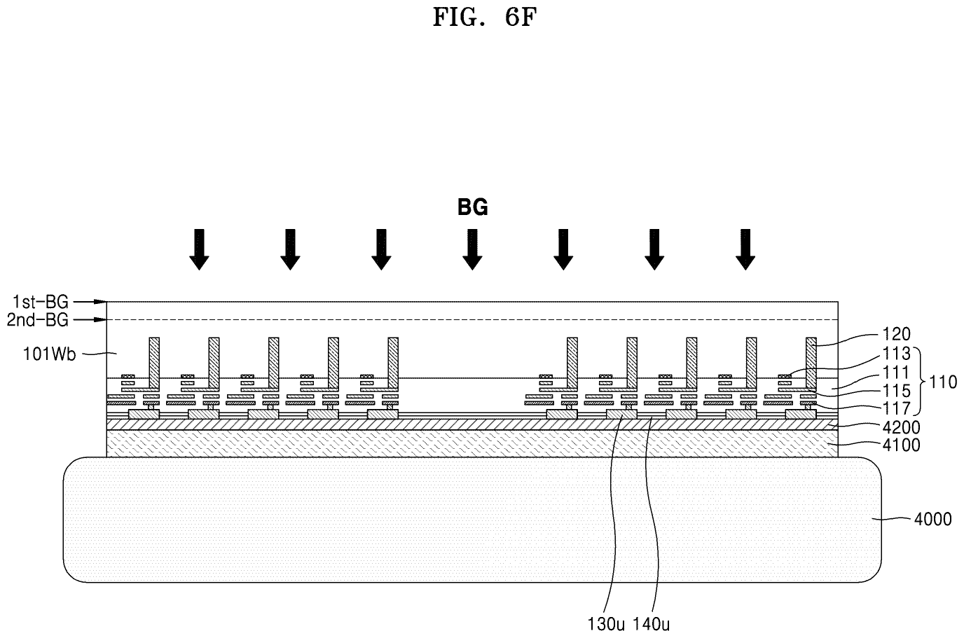

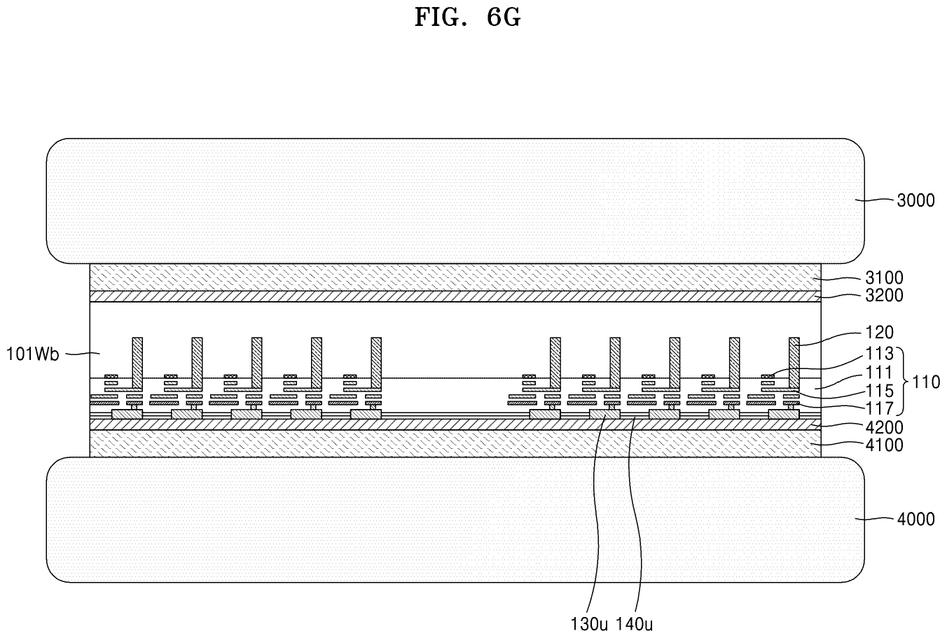

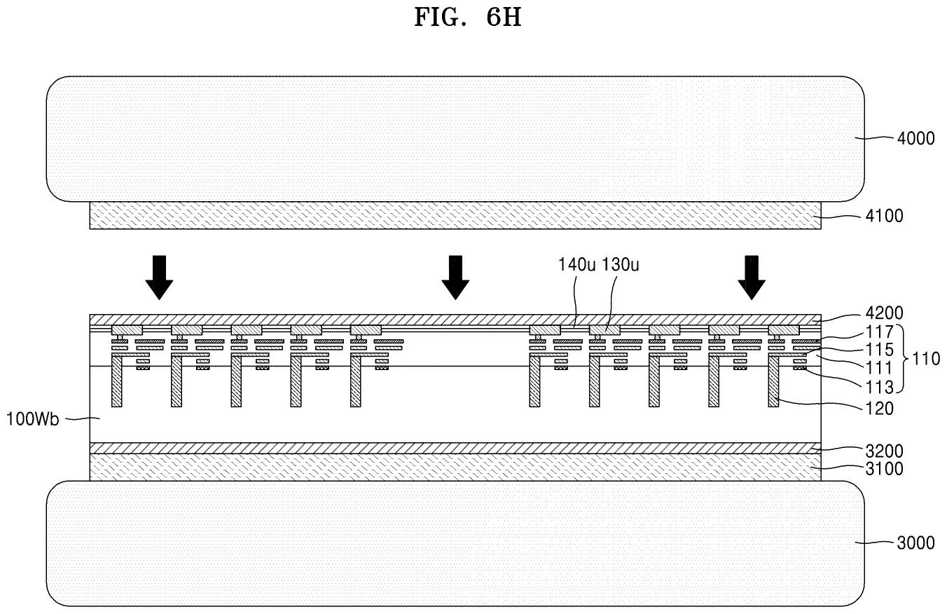

Each of the initial first semiconductor chips may include a first semiconductor substrate 101Wb, the first active layer 110, the through-electrode 120, an upper pad 130u, and an upper protective layer 140u. The first semiconductor substrate 101Wb, the first active layer 110, the through-electrode 120, the upper pad 130u, and the upper protective layer 140u are the same as those of the first semiconductor chip 100 of the semiconductor package 1000 described above with reference to FIG. 1A. The process of forming a plurality of initial first semiconductor chips on the first semiconductor substrate 101Wb is described in more detail below with reference to FIGS. 6A to 6H.

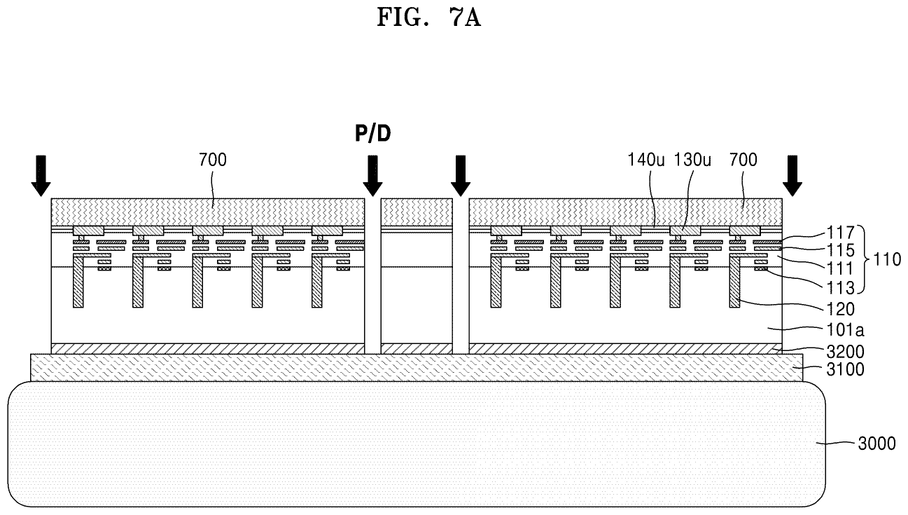

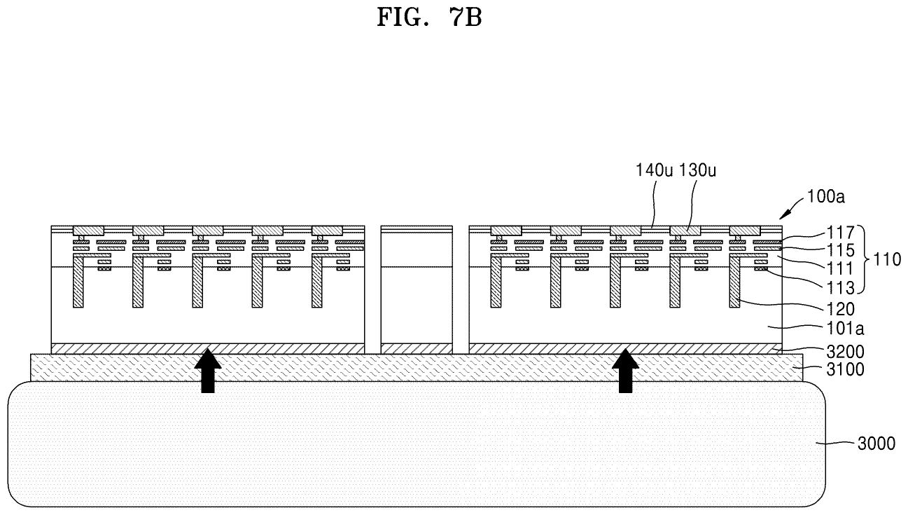

Referring to FIG. 5B, the initial first semiconductor chips 100a are then individualized through a plasma dicing process P/D. The plasma dicing process P/D is described in more detail below with reference to FIGS. 7A and 7B. Meanwhile, in the method of manufacturing a semiconductor package of the present embodiment, the individualization of the initial first semiconductor chips 100a is not limited to the plasma dicing process P/D. For example, the initial first semiconductor chips 100a may be individualized through a blade dicing process or a laser dicing process. Meanwhile, the dicing process may also be referred to as a sawing process.

Referring to FIG. 5C, after individualization into the initial first semiconductor chips 100a, the initial first semiconductor chips 100a are stacked on initial second semiconductor chips through HCB. In the stacking process using HCB, a thermal compression bonding (TCB) method may be applied. The initial first semiconductor chips 100a may be stacked on the corresponding initial second semiconductor chips, respectively.

Meanwhile, prior to stacking the initial first semiconductor chips 100a, a process of forming initial second semiconductor chips on a second semiconductor substrate 201W may be performed. For example, the process of forming initial second semiconductor chips on the second semiconductor substrate 201W may be performed in parallel and/or independently from the process of forming the initial first semiconductor chips on the first semiconductor substrate 101Wb. Each of the initial second semiconductor chips may include the second semiconductor substrate 201W, a second active layer 210a, a second chip pad 230, and a second protective layer 240. The second semiconductor substrate 201W, the second active layer 210a, the second chip pad 230, and the second protective layer 240 are the same as those of the second semiconductor chip 200 of the semiconductor package 1000 described above with reference to FIG. 1A.

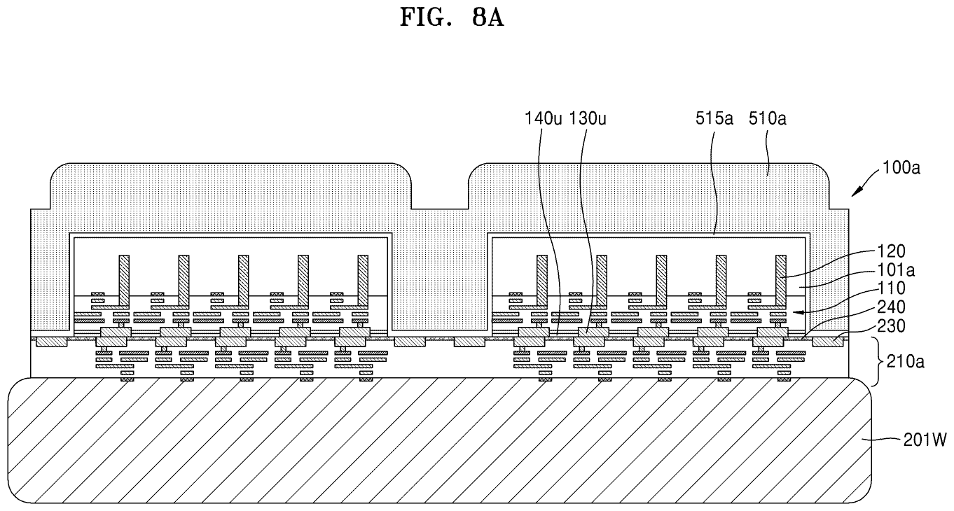

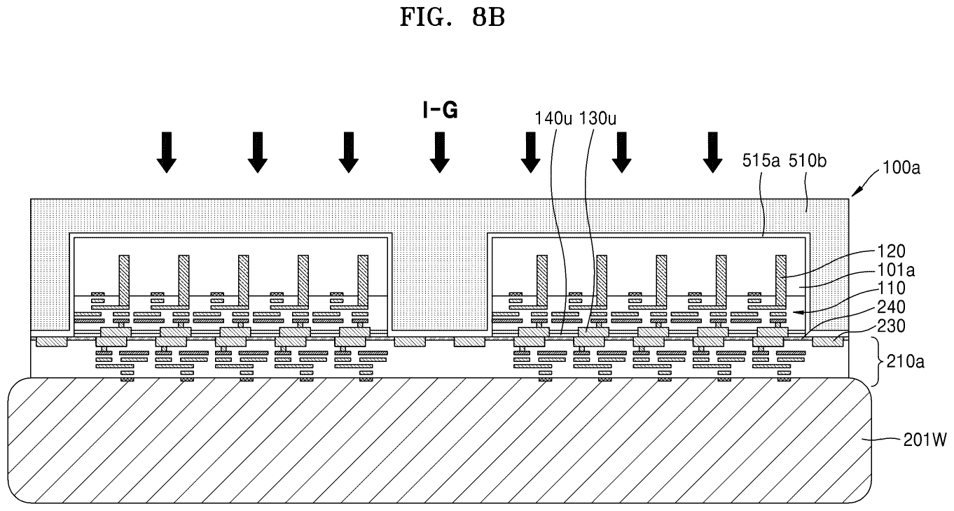

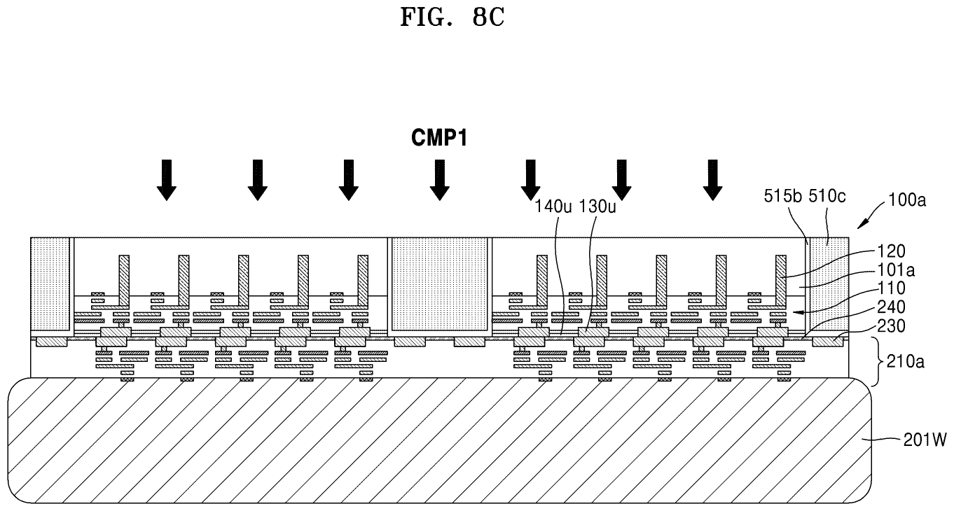

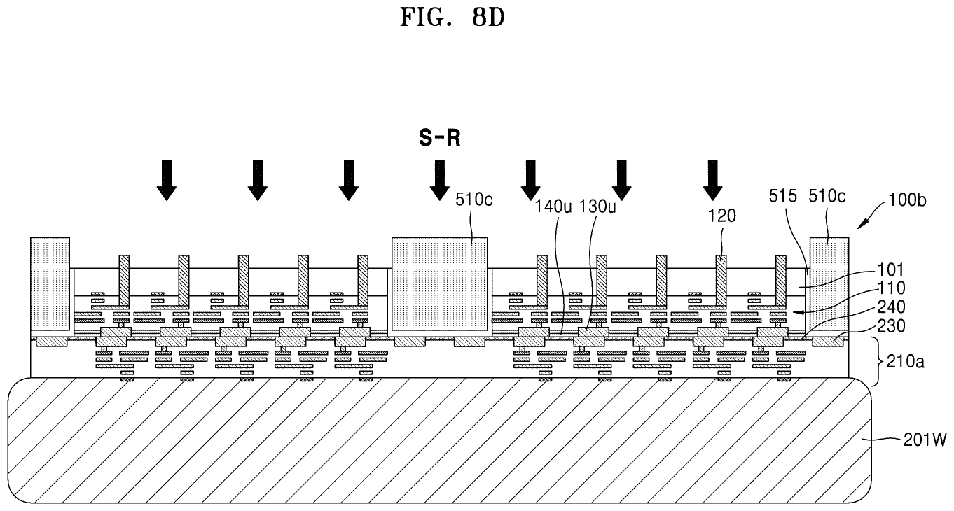

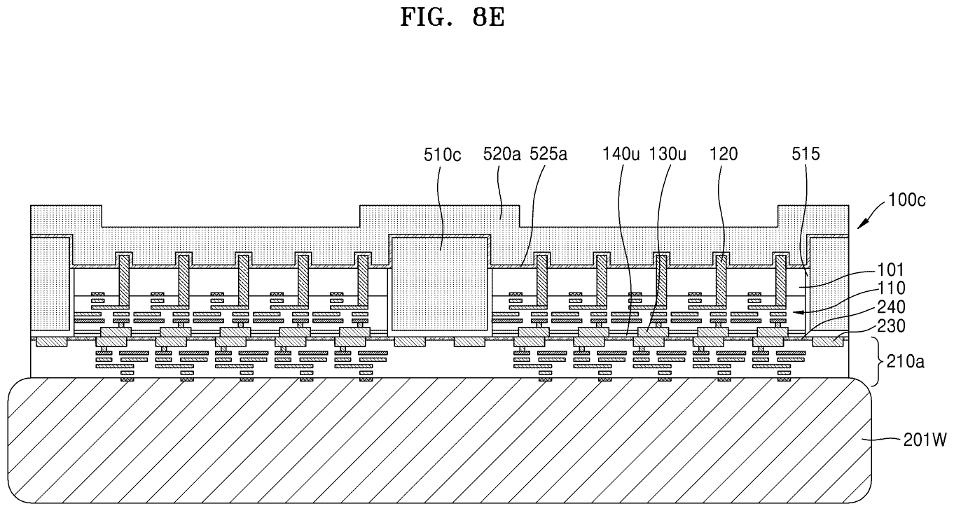

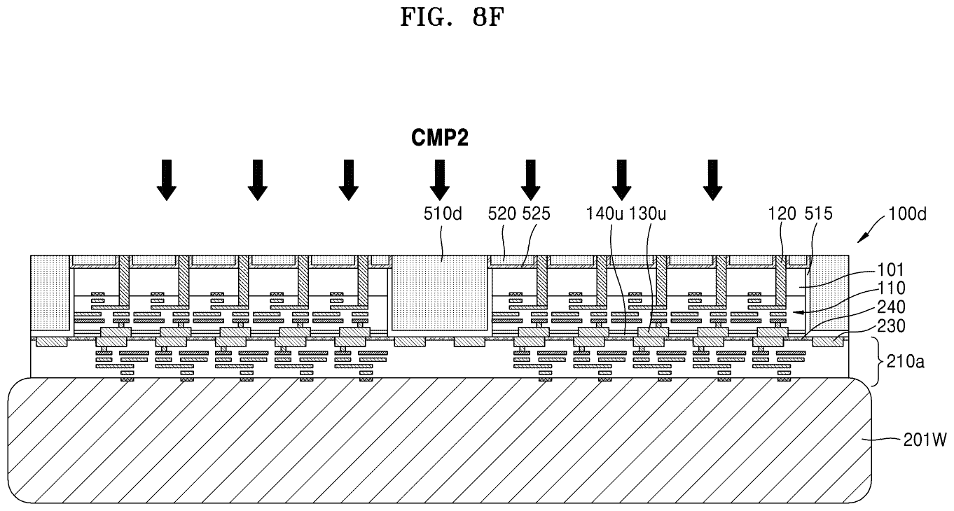

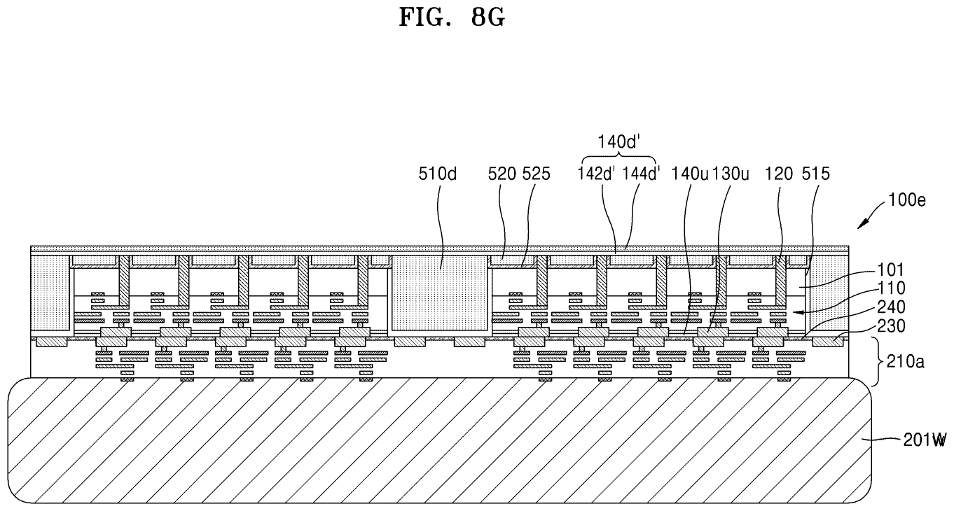

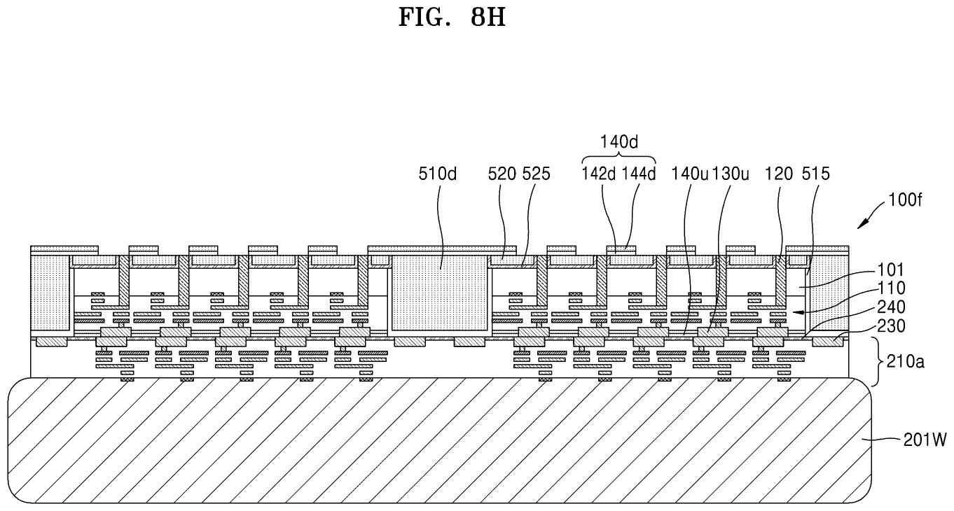

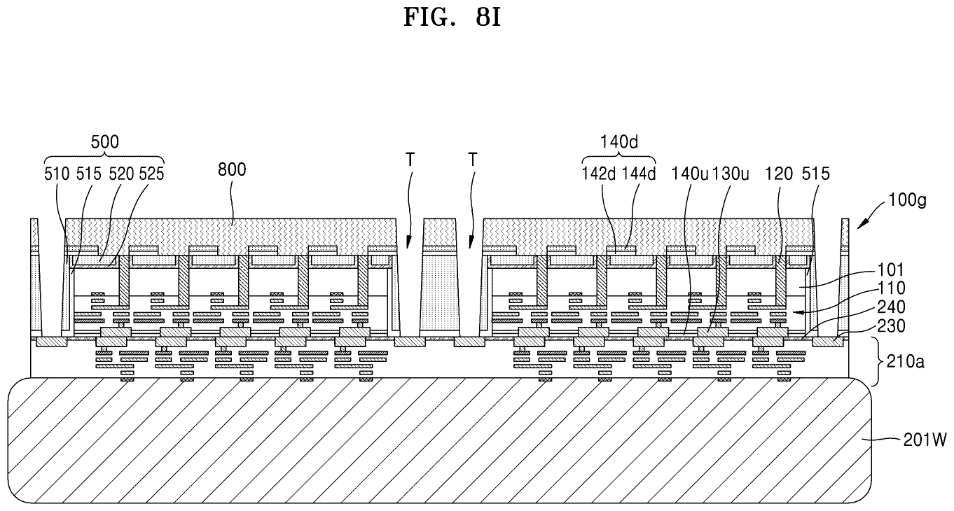

Referring to FIG. 5D, after stacking the initial first semiconductor chips 100a, the sealant 500 covering the initial first semiconductor chips 100a and the lower protective layer 140d are formed. In addition, the lower pad 130d is formed on each of the initial first semiconductor chips 100a, and the external through-electrode 400 is formed between the initial first semiconductor chips 100a. The lower pad 130d and the external through-electrode 400 may be formed together through a plating process. The process of forming the lower pad 130d and the external through-electrode 400 is described in more detail below with reference to FIGS. 8A to 8I.

Referring to FIG. 5E, after forming the sealant 500, the lower protective layer 140d, the lower pad 130d, and the external through-electrode 400, a package protective layer 330a is formed on the sealant 500, the lower protective layer 140d, the lower pad 130d, and the external through-electrode 400. The package protective layer 330a may include, for example, SR. However, the material of the package protective layer 330a is not limited to SR.

Referring to FIG. 5F, after the formation of the package protective layer 330a, the package protective layer 330a is patterned to expose the lower pad 130d, and the external connection terminal 300 is formed on the lower pad 130d. In detail, the external connection terminal 300 may be placed on the lower pad 130d connected to the through-electrode 120 and the lower pad 130d connected to the external through-electrode 400. The external connection terminal 300 is the same as the external connection terminal 300 of the semiconductor package 1000 described above with reference to FIG. 1A.

Referring to FIG. 5G, thereafter, a sawing process S may be performed to individualize the semiconductor packages, thereby completing the semiconductor package 1000 of FIG. 1A. The sawing process S may be performed, for example, in a ring mounting device.

FIGS. 6A to 6H are cross-sectional views illustrating the process of operation of FIG. 5A in more detail. Descriptions are given with reference to FIGS. 1A and 1B together, and the descriptions already given above with reference to FIGS. 1A to 5G are briefly given or omitted.

Referring to FIG. 6A, a first integrated circuit layer is formed on the first semiconductor substrate 101W. The first integrated circuit layer may include, for example, integrated devices 113 and interconnections connected to the integrated devices 113. Here, the integrated device 113 may include, for example, a transistor. However, the integrated device 113 is not limited to a transistor.

Referring to FIG. 6B, after the formation of the first integrated circuit layer, a through-electrode 120 is formed that penetrates a portion of the first semiconductor substrate 101W. After the formation of the first integrated circuit layer, the through-electrode 120 is formed, so the through-electrode 120 may correspond to a via-middle structure. The through-electrode 120 is the same the through-electrode 120 of the semiconductor package 1000 described above with reference to FIG. 1A.

Referring to FIG. 6C, after forming the through-electrode, a first interconnection layer is formed on the first integrated circuit layer and the through-electrode 120. The first interconnection layer may include the interlayer insulating layer 111, the interconnections 115, and the internal pad 117. The internal pad 117 may include, for example, aluminum (Al). However, the material of the internal pad 117 is not limited to Al.

After the first interconnection layer is formed, the first interconnection layer is flattened. As described above, the first integrated circuit layer and the first interconnection layer may form a first active layer 110 on the first semiconductor substrate 101W. Thereafter, the upper pad 130u and the upper protective layer 140u are formed on the first active layer 110. The upper pad 130u and the upper protective layer 140u are the same as the upper pad 130u and the upper protective layer 140u of the semiconductor package 1000 described above with reference to FIG. 1A.

Referring to FIG. 6D, after the formation of the upper pad 130u and the upper protective layer 140u, a trimming process is performed on the first semiconductor substrate 101W, thereby forming the first semiconductor substrate 101Wa with a cutting portion CP formed in an outer portion. After the trim process, a cleaning process and/or a buffing CMP process may be additionally performed. Through the buffing CMP process, the upper surfaces of the upper pad 130u and the upper protective layer 140u may be flattened and the roughness may be reduced.

Referring to FIG. 6E, after the formation of the cutting portion CP, the first semiconductor substrate 101Wa and the entire upper structure are bonded and fixed to a second carrier substrate 4000 through an adhesive layer. The adhesive layer may include, for example, a TBM layer 4100 and a release layer 4200. The first semiconductor substrate 101Wa and the upper structure may be bonded so that the upper pad 130u and the upper protective layer 140u face the second carrier substrate 4000, as shown in FIG. 6E.

Referring to FIG. 6F, thereafter, a back-grinding process BG is performed on the first semiconductor substrate 101Wa to remove a portion of a rear surface of the first semiconductor substrate 101Wa. The back-grinding process BG may proceed up to a first level (1st-BG). The first level (1st-BG) may have a sufficient distance from the through-electrode 120 as indicated by the solid line. However, in some embodiments, the back-grinding process BG may proceed up to a second level (2nd-BG) indicated by the dashed line. In the operation of FIG. 6F, when the back-grinding process BG is performed up to the second level (2nd-BG), an additional back-grinding process may be omitted thereafter.

Referring to FIG. 6G, after the back-grinding process BG, the first carrier substrate 3000 is bonded to a rear surface of the first semiconductor substrate 101Wb through an adhesive layer. The adhesive layer may include, for example, the TBM layer 3100 and the release layer 3200.

Referring to FIG. 6H, after bonding the first carrier substrate 3000, the second carrier substrate 4000 is separated from the first semiconductor substrate 101Wb and the upper structure. Separation of the second carrier substrate 4000 may be accomplished through irradiation with a UV laser. As illustrated in FIG. 6H, in the process of separating the second carrier substrate 4000 through irradiation with a UV laser, the release layer 4200 may be maintained on the upper pad 130u and the upper protective layer 140u. The release layer 4200 may be removed through a cleaning process, etc. By removing the release layer 4200, the process of forming a plurality of initial first semiconductor chips on the first semiconductor substrate 101Wb of the operation of FIG. 5A may be completed.

For reference, the process of combining carriers for the back-grinding process or dicing process and separating the carriers after the corresponding process is referred to as a wafer supporting system (WSS) process. In addition, the WSS process may include a WSS bonding process for bonding the carriers and a WSS debonding process for separating the carriers.

FIGS. 7A and 7B are cross-sectional views illustrating the process from the operation of FIG. 5A to the operation of FIG. 5B in more detail. Descriptions are given with reference to FIGS. 1A and 1B together, and the descriptions already given above with reference to FIGS. 1A to 6H are briefly given or omitted.

Referring to FIG. 7A, after forming the initial first semiconductor chips on the first semiconductor substrate 101Wb in FIG. 5A, a photoresist (PR) pattern 700 is formed on the initial first semiconductor chips. The PR pattern 700 may have a form covering each of the initial first semiconductor chips. Thereafter, the first semiconductor substrate 101Wb and the upper structure are individually divided into the initial first semiconductor chips 100a through a plasma dicing process P/D. The plasma dicing process P/D may be performed by etching using plasma using the PR pattern 700 as a mask.

For reference, in the plasma dicing process P/D for wafers, first, a protective tape or protective layer coating (PLC) is formed on a wafer including a number of semiconductor chips. Thereafter, scribe lanes between the semiconductor chips are removed through a laser grooving process. Laser grooving may be referred to as laser sawing. In addition, blade sawing may be performed instead of laser sawing. Meanwhile, the scribe lanes may not be completely removed through the laser grooving process. Therefore, a plasma dicing process P/D may be performed to completely remove the scribe lanes. In the plasma dicing process P/D, the protective tape or PLC may act as a mask. In the method of manufacturing a semiconductor package of the present embodiment, a laser grooving process using a protective tape or PLC, etc., instead of the PR pattern 700, may be performed first, and then the plasma dicing process P/D may be performed.

Referring to FIG. 7B, after the plasma dicing process P/D, the PR pattern 700 is removed, and as indicated by the arrow, UV laser irradiation is performed on the release layer 3200, thereby separating each of the initial first semiconductor chips 100a from the first carrier substrate 3000. As can be seen from FIG. 5B, the release layer 3200 may be maintained on the lower surface of each of the initial first semiconductor chips 100a, and the release layer 3200 may be removed through a cleaning process after stacking the initial first semiconductor chips 100a on the initial second semiconductor chips.

FIGS. 8A to 8I are cross-sectional views illustrating the progression from the operation of FIG. 5C to the operation of FIG. 5D in more detail. Descriptions are given with reference to FIGS. 1A and 1B together, and the descriptions already given above with reference to FIGS. 1A to 7B are briefly given or omitted.

Referring to FIG. 8A, after stacking the initial first semiconductor chips 100a in FIG. 5C, an additional back-grinding process may be performed to reduce the thickness of the initial first semiconductor chips 100a. Through the additional back-grinding process, the thickness of the initial first semiconductor chips 100a may be reduced to the second level (2nd-BG) of FIG. 6F.

After the additional back-grinding process, a first gapfill liner 515a is formed to cover the upper surface and side surfaces of the initial first semiconductor chips 100a. Subsequently, a first sealing layer 510a is formed on the first gapfill liner 515a. The first sealing layer 510a may cover the upper surfaces of the initial first semiconductor chips 100a and may also fill a gap between the initial first semiconductor chips 100a. For example, the first gapfill liner 515a may include a silicon nitride film, and the first sealing layer 510a may include a silicon oxide film. However, the materials of the first gap fill liner 515a and the first sealing layer 510a are not limited to the materials described above.

Referring to FIG. 8B, after the formation of the first gap fill liner 515a and the first sealing layer 510a, an insulating film-grinding process IG is performed to remove an upper portion of the first sealing layer 510a. Through the insulating film-grinding process IG, the upper surface of the first sealing layer 510a may be flattened and the first sealing layer 510a may thus become a flattened first sealing layer 510b. When the first sealing layer 510a includes an oxide film, the insulating film-grinding process IG may correspond to an oxide film-grinding process.

Referring to FIG. 8C, after the insulating film-grinding process IG, a first CMP process CMP1 is performed to remove a portion of the first sealing layer 510b and a portion of the first gapfill liner 515a on the upper portion of the first semiconductor substrate 101a. Through the first CMP process CMP1, the first sealing layer 510c and the first gapfill liner 515b may be maintained only on the side surface of the first semiconductor substrate 101a.

Referring to FIG. 8D, after the first CMP process CMP1, a semiconductor-recess process S-R is performed to remove an upper portion of the first semiconductor substrate 101a. Through the semiconductor-recess process S-R, the through-electrode 120 may protrude from the upper surface of the first semiconductor substrate 101. The semiconductor-recess process S-R may be performed through a dry-etch process. However, in some embodiments, the semiconductor-recess process S-R may utilize a wet-etch process. For reference, here, the upper surface of the first semiconductor substrate 101 may correspond to the lower surface of the first semiconductor substrate 101 of the first semiconductor chip 100 in the semiconductor package 1000 of FIG. 1A.

In the semiconductor-recess process S-R, the upper portion of the first gapfill liner 515b may also be removed. The first gapfill liner 515 may be formed by removing the upper portion of the first gapfill liner 515b. Meanwhile, because the first semiconductor substrate 101 includes Si, the semiconductor-recess process S-R may correspond to a Si-recess process.

Referring to FIG. 8E, after the semiconductor-recess process S-R, the second gapfill liner 525a covering the initial first semiconductor chips 100b and the first sealing layer 510c is formed. Subsequently, the second sealing layer 520a is formed on the second gapfill liner 525a. For example, the second gapfill liner 525a may include a silicon nitride film, and the second sealing layer 520a may include a silicon oxide film. However, the materials of the second gap fill liner 525a and the second sealing layer 520a are not limited to the materials described above.

Referring to FIG. 8F, after the formation of the second gapfill liner 525a and the second sealing layer 520a, a second CMP process CMP2 is performed on the first sealing layer 510c, the second gapfill liner 525a, and the second sealing layer 520a. Through the second CMP process CMP2, the upper surface of the through-electrode 120 may be exposed. In addition, through the second CMP process CMP2, the first sealing layer 510d may be maintained on the side surface of the first semiconductor substrate 101, and the second gap fill liner 525 and the lower sealant 520 may be formed on the upper surface of the first semiconductor substrate 101. For reference, here, the upper surface of the through-electrode 120 may correspond to the lower surface of the through-electrode 120 of the first semiconductor chip 100 in the semiconductor package 1000 of FIG. 1A.

Referring to FIG. 8G, after the second CMP process CMP2, a lower protective layer 140d′ is formed on the through-electrode 120, the first sealing layer 510d, the second gapfill liner 525, and the lower sealant 520. The lower protective layer 140d′ may include a first lower insulating layer 142d′ and a second lower insulating layer 144d'. For example, the first insulating layer 142d′ may include a silicon carbon nitride film (SiCN), and the second insulating layer 144d′ may include a silicon oxide film. However, the materials of the first insulating layer 142d′ and the second insulating layer 144d′ are not limited to the materials described above.

Referring to FIG. 8H, after the formation of the lower protective layer 140d′, the lower protective layer 140d′ is patterned to form the lower protective layer 140d. The lower protective layer 140d may include an open portion. The upper surface of the through-electrode 120 may be exposed through the open portion of the lower protective layer 140d. Patterning of the lower protective layer 140d′ may be performed through an exposure process.

Referring to FIG. 8I, after the formation of the lower protective layer 140d, the first sealing layer 510d is patterned to form the side sealant 510. The side sealant 510 may include a trench T. A second chip pad 230 may be exposed through a bottom surface of the trench T of the side sealant 510. Patterning of the first sealing layer 510d may be performed through an exposure process using a PR layer 800. Thereafter, the PR layer 800 may be removed, and the open portion of the lower protective layer 140d and the trench T of the side sealant 510 may be filled with a metal, for example, Cu, through a plating process.

Subsequently, Cu of an outer portion of the open portion and trench T is removed through a CMP process. By removing Cu from the outer portion of the open portion and the trench T, the lower pad 130d may be formed in the open portion and the external through-electrode 400 may be formed in the trench T, as shown in FIG. 5D. Because the lower pad 130d and the external through-electrode 400 are formed together through the plating process and the CMP process, the upper surfaces of the lower pad 130d and the external through-electrode 400 may form the same plane. For reference, here, the upper surfaces of the lower pad 130d and the external through-electrode 400 may correspond to the lower surfaces of the lower pad 130d and the external through-electrode 400 of the first semiconductor chip 100 in the semiconductor package 1000 of FIG. 1A.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first semiconductor chip having a first upper surface which is an active surface and a first lower surface opposite to the first upper surface, and having a through-electrode arranged in the first semiconductor chip;
a second semiconductor chip stacked on the first semiconductor chip, the second semiconductor chip having a second lower surface which is an active surface and a second upper surface opposite to the second lower surface and having a size larger than the first semiconductor chip in a horizontal direction; and
an external through-electrode placed below the second semiconductor chip and adjacent to the first semiconductor chip,
wherein the second semiconductor chip is stacked on the first semiconductor chip through hybrid copper bonding (HCB).

2. The semiconductor package of claim 1, wherein
the first semiconductor chip includes a first upper pad on the first upper surface and a first lower pad on the first lower surface,
the second semiconductor chip includes a second lower pad on the second lower surface, and
a lower surface of the external through-electrode is substantially coplanar with a lower surface of the first lower pad.

3. The semiconductor package of claim 2, wherein
an upper surface of the external through-electrode is connected to the second lower pad, and
external connection terminals are respectively placed on a lower surface of the external through-electrode and a lower surface of the first lower pad.

4. The semiconductor package of claim 2, further comprising:
a redistribution layer placed below the external through-electrode and the first semiconductor chip,
wherein an external connection terminal is placed on a lower surface of the redistribution layer.

5. The semiconductor package of claim 2, wherein
the HCB includes bonding between the first upper pad and the second lower pad and bonding between an upper protective layer of the first semiconductor chip and a lower protective layer of the second semiconductor chip.

6. The semiconductor package of claim 2, wherein the first lower pad is directly connected to the through-electrode.

7. The semiconductor package of claim 2, wherein the first upper pad is connected to the through-electrode through a multi-interconnection layer of the first semiconductor chip.

8. The semiconductor package of claim 2, wherein the first upper pad is spaced apart from the through-electrode.

9. The semiconductor package of claim 1, wherein
the first semiconductor chip includes a logic chip or a memory chip,
the second semiconductor chip includes a logic chip.

10. A semiconductor package comprising:
a first semiconductor chip having a first upper surface which is an active surface and a first lower surface opposite to the first upper surface and having a through-electrode arranged in the first semiconductor chip;
a second semiconductor chip stacked on the first semiconductor chip, the second semiconductor chip having a second lower surface which is an active surface and a second upper surface opposite to the second lower surface and having a larger size than the first semiconductor chip in a horizontal direction;
a sealant sealing the first semiconductor chip on a lower surface of the second semiconductor chip;
an external through-electrode placed below the second semiconductor chip and adjacent to the first semiconductor chip, the external through-electrode penetrating the sealant; and
external connection terminals respectively arranged on a lower surface of the external through-electrode and a lower surface of a first lower pad disposed on the first lower surface of the first semiconductor chip,
wherein the second semiconductor chip is stacked on the first semiconductor chip through hybrid copper bonding (HCB), and
the lower surface of the external through-electrode is substantially coplanar with the lower surface of the first lower pad.

11. The semiconductor package of claim 10, wherein
the first semiconductor chip includes a first upper pad on the first upper surface,
the second semiconductor chip includes a second lower pad on the second lower surface, and
the HCB includes bonding between the first upper pad and the second lower pad and bonding between an upper protective layer of the first semiconductor chip and a lower protective layer of the second semiconductor chip.

12. The semiconductor package of claim 10, wherein
the first semiconductor chip includes a first upper pad on the first upper surface,
the first lower pad is directly connected to the through-electrode, and
the first upper pad is connected to the through-electrode through a multi-interconnection layer of the first semiconductor chip.

13. The semiconductor package of claim 10, wherein
the first semiconductor chip includes a first upper pad on the first upper surface, and
the first upper pad is spaced apart from the through-electrode.

14. A semiconductor package comprising:
a package substrate;
a first semiconductor device on the package substrate; and
at least one second semiconductor device placed on the package substrate and adjacent to the first semiconductor device,
wherein the first semiconductor device has a package structure including a first semiconductor chip having a first upper surface as an active surface and a first lower surface opposite to the first upper surface and having a through-electrode arranged in the first semiconductor chip, a second semiconductor chip stacked on the first semiconductor chip, having a second lower surface as an active surface and a second upper surface opposite to the second lower surface, and having a larger size than the first semiconductor chip in a horizontal direction, and an external through-electrode placed below the second semiconductor chip and adjacent to the first semiconductor chip, and
the second semiconductor chip is stacked on the first semiconductor chip through hybrid copper bonding (HCB).

15. The semiconductor package of claim 14, wherein
the first semiconductor chip includes a first upper pad on the first upper surface and a first lower pad on the first lower surface,
the second semiconductor chip includes a second lower pad on the second lower surface, and
a lower surface of the external through-electrode is substantially coplanar with a lower surface of the first lower pad.

16. The semiconductor package of claim 15, wherein
the first lower pad is directly connected to the through-electrode, and
the first upper pad is connected to the through-electrode through a multi-interconnection layer of the first semiconductor chip.

17. The semiconductor package of claim 15, wherein the first upper pad is spaced apart from the through-electrode.

18. The semiconductor package of claim 15, wherein
the HCB includes bonding between the first upper pad and the second lower pad and bonding between an upper protective layer of the first semiconductor chip and a lower protective layer of the second semiconductor chip.

19. The semiconductor package of claim 14, wherein
the first semiconductor device includes a logic chip, and
the second semiconductor device includes a high bandwidth memory package.

20. The semiconductor package of claim 14, further comprising:
an intermediate substrate placed on the package substrate or a silicon-bridge located within the package substrate,
wherein the first semiconductor device is connected to the second semiconductor device through the intermediate substrate or the silicon bridge.
